(19) United States
(12) Patent Application Publication
(10) Pub. No.: US 2025/0251665 A1
(43) Pub. Date: Aug. 7, 2025

(54) PHOTOSENSITIVE RESIN COMPOSITION, PHOTOSENSITIVE RESIN FILM, PHOTOSENSITIVE DRY FILM, AND PATTERN FORMING PROCESS

(71) Applicant: SHIN-ETSU CHEMICAL CO., LTD., Tokyo (JP)

(72) Inventors: Kumiko KUMAZAWA, Tomioka-shi (JP); Hitoshi Maruyama, Annaka-shi (JP)

(73) Assignee: SHIN-ETSU CHEMICAL CO., LTD., Tokyo (JP)

(21) Appl. No.: 19/035,374

(22) Filed: Jan. 23, 2025

(30) Foreign Application Priority Data
Feb. 2, 2024 (JP) 2024-015069

(51) Int. Cl. G03F 7/075; G03F 7/004; G03F 7/40

(52) U.S. Cl. CPC G03F 7/0757; G03F 7/0045; G03F 7/40

(57) ABSTRACT

The present invention is a photosensitive resin composition including a silicone skeleton-containing polymer (A), an anthraquinone-based dye (B), and a photoacid generator (C). The inventive photosensitive resin composition can provide: a photosensitive resin composition which can provide a photosensitive resin film that has a shielding function, has dispersion stability in varnish, can reduce aggregates in a film, and can form a fine pattern; a photosensitive resin film; a photosensitive dry film; and a pattern forming process by using the compositions.

### TECHNICAL FIELD

The present invention relates to a photosensitive resin composition, a photosensitive resin film, a photosensitive dry film, and a pattern forming process.

### BACKGROUND ART

Some optical devices have a hollow structure in which the optical device is attached to the cover glass by a partition formed around its sensor, and this partition is generally formed by a lithography process using a photosensitive resin composition. Normally, the sensor receives information by light that enters from the cover glass side. However, if leakage light enters also from the partition side, problems will occur in image processing, so the device is required to have a light-shielding function. As a photosensitive resin composition for such a cured film having a light-shielding function, it has been proposed a material in which a photosensitive silicone composition mainly composed of a silphenylene skeleton-containing silicone-type polymer is blended with a carbon black (Patent Literature 1).

However, there are problems in that carbon black precipitates in the varnish and that aggregates remain in the cured film. Furthermore, it is desired to further improve the level of miniaturization through pattern formation also.

### CITATION LIST

### Patent Literature

Patent Document 1: JP2013-016879A

### SUMMARY OF INVENTION

### Technical Problem

The present invention was made in view of the above circumstances, and has objects to provide: a photosensitive resin composition capable of providing a photosensitive resin film that has a shielding function, has dispersion stability in varnish, can reduce aggregates in a film, and can form a fine pattern; a photosensitive resin film; and a photosensitive dry film; and a pattern forming process by using these compositions.

### Solution to Problem

To solve the above problems, the present invention provides a photosensitive resin composition comprising a silicone skeleton-containing polymer (A), an anthraquinone-based dye (B), and a photoacid generator (C).

The inventive photosensitive resin composition can provide: a photosensitive resin composition, a photosensitive resin film, and a photosensitive dry film, which contain an anthraquinone-based dye capable of providing a photosensitive resin film that has a shielding function, has dispersion stability in varnish, can reduce aggregates in a film, and can form a fine pattern; a pattern forming process by using these compositions; and a pattern forming process by using the photosensitive dry film.

Further, in the inventive photosensitive resin composition, the silicone skeleton-containing polymer (A) preferably comprises repeating units represented by the following formulae (a1) to (a4) and (b1) to (b4).

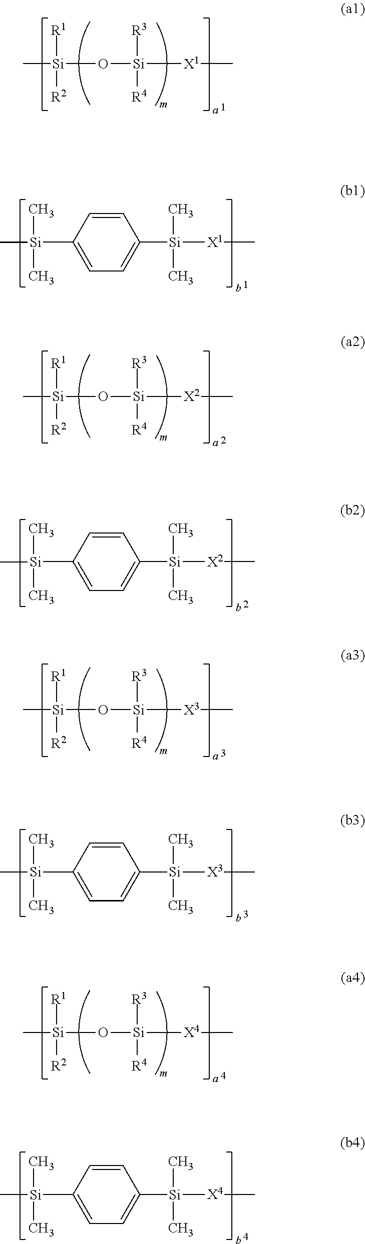

In the formulae, R¹ to R⁴ each independently represent a monovalent hydrocarbon group having 1 to 8 carbon atoms. “m” represents an integer of 1 to 600.

a¹ to a⁴ and b¹ to b⁴ represent numbers satisfying 0≤a¹<1, 0≤a²<1, 0≤a³<1, 0≤a⁴<1, 0≤b¹<1, 0≤b²<1, 0≤b³<1, 0≤b⁴<1, 0<a¹+a²+a³+a⁴<1, 0<b¹+b²+b³+b⁴<1, and a¹+a²+a³+a⁴+b¹+b²+b³+b⁴=1.

X¹ represents a divalent group represented by the following formula (X1). X² represents a divalent group represented by the following formula (X2). X³ represents a divalent group represented by the following formula (X3). X⁴ represents a divalent group represented by the following formula (X4).

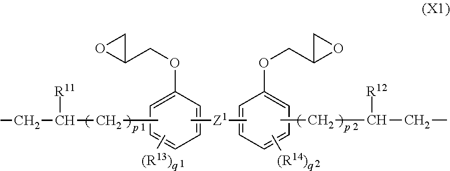

In the formula, Z¹ represents a single bond, a methylene group, a propane-2,2-diyl group, a 1,1,1,3,3,3-hexafluoropropane-2,2-diyl group, or a fluorene-9,9-diyl group. R¹¹ and R¹² each independently represent a hydrogen atom or a methyl group. R¹³ and R¹⁴ each independently represent an alkyl group having 1 to 4 carbon atoms or an alkoxy group having 1 to 4 carbon atoms. p¹ and p² each independently represent an integer of 0 to 7. q¹ and q² each independently represent an integer of 0 to 2.

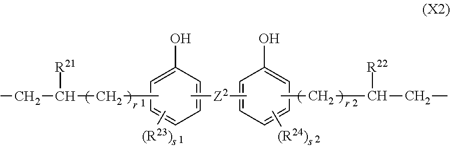

In the formula, Z² represents a single bond, a methylene group, a propane-2,2-diyl group, a 1,1,1,3,3,3-hexafluoropropane-2,2-diyl group, or a fluorene-9,9-diyl group. R²¹ and R²² each independently represent a hydrogen atom or a methyl group. R²³ and R²⁴ each independently represent an alkyl group having 1 to 4 carbon atoms or an alkoxy group having 1 to 4 carbon atoms. r¹ and r² each independently represent an integer of 0 to 7. s¹ and s² each independently represent an integer of 0 to 2.

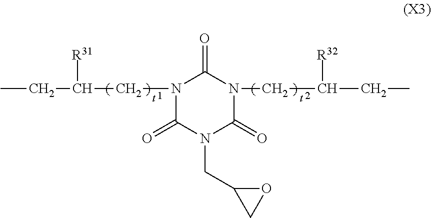

In the formula, R³¹ and R³² each independently represent a hydrogen atom or a methyl group. t¹ and t² each independently represent an integer of 0 to 7.

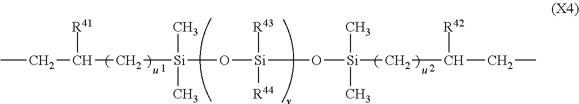

In the formula, R⁴¹ and R⁴² each independently represent a hydrogen atom or a methyl group. R⁴³ and R⁴⁴ each independently represent a monovalent hydrocarbon group having 1 to 8 carbon atoms. u¹ and u² each independently represent an integer of 0 to 7. “v” represents an integer of 0 to 600.

The inventive photosensitive resin composition as such can provide a photosensitive resin film that have good adhesiveness to a laminate and a substrate etc., good pattern formability, crack resistance, and heat resistance.

Further, the inventive photosensitive resin composition preferably comprises any one or more of a crosslinking agent (D), a solvent (E), a quencher (F), and an antioxidant (G).

Such a photosensitive resin composition can form a pattern easily and further improve strength of the cured product. Further, it is possible to enhance its resolution, suppress sensitivity change after light exposure, reduce substrate dependence or environmental dependence, and improve exposure latitude or a pattern profile.

Further, in the inventive photosensitive resin composition, the anthraquinone-based dye (B) is preferably contained in a 0.01 to 50 parts by mass relative to 100 parts by mass of the above component (A)

Further, in the inventive photosensitive resin composition, the anthraquinone-based dye (B) preferably has an absorption maximum wavelength of 800 nm or less.

Such a photosensitive resin composition can give a higher shielding function, can have dispersion stability in varnish, can reduce aggregates in a film, and further can form a fine pattern.

The inventive photosensitive resin composition is preferably used for an optical member.

Such a photosensitive resin composition is excellent in dispersion stability in varnish, can reduce aggregates in a film, and can be used as a material for an optical member that need shielding.

The present invention provides a photosensitive resin film obtained from the inventive photosensitive resin composition.

Such a photosensitive resin film has a shielding function, has dispersion stability in varnish, can reduce aggregates in a film, and can form a fine pattern.

Further, the present invention provides a photosensitive dry film comprising a support film and the inventive photosensitive resin film on the support film.

With such a photosensitive dry film, it is possible to obtain the inventive photosensitive resin film having a desired thickness easily.

The present invention provides a pattern forming process by using the inventive photosensitive resin composition, comprising:
forming a photosensitive resin film on a substrate by using the inventive photosensitive resin composition;
exposing the photosensitive resin film; and
developing the exposed photosensitive resin film with a developer to form a pattern.

Further, the present invention provides a pattern forming process by using the above inventive photosensitive dry film, comprising:
forming a photosensitive resin film on a substrate by using the photosensitive dry film;
exposing the photosensitive resin film; and
developing the exposed photosensitive resin film with a developer to form a pattern.

By such a pattern forming process, it is possible to form a contact hole pattern having good verticality.

Further, the pattern forming process by using the above inventive photosensitive resin composition, preferably comprises post-curing the photosensitive resin film at a temperature of 100° C. to 250° C., which has a pattern formed by development.

By such a pattern forming process including post-curing, it is possible to increase crosslinking density of the inventive photosensitive resin composition and remove remaining volatile components. Additionally, the pattern forming process is more preferable from the point of view of adhesiveness to a substrate, heat resistance, strength, electric properties, further and adhesive strength.

### Advantageous Effects of Invention

As described above, the inventive photosensitive resin composition can provide: a photosensitive resin composition, a photosensitive resin film, and a photosensitive dry film, which contain an anthraquinone-based dye capable of providing a photosensitive resin film that has a shielding function, has dispersion stability in varnish, can reduce aggregates in a film, and can form a fine pattern; a pattern forming process by using these compositions; and a pattern forming process by using the photosensitive dry film.

### DESCRIPTION OF EMBODIMENTS

As described above, it has been desired to develop a photosensitive resin composition capable of providing a photosensitive resin film that has a shielding function, has dispersion stability in varnish, can reduce aggregates in a film, and can form a fine pattern.

As a result of their diligent study of the above problems, the inventors found that by using an anthraquinone-based dye as a light-absorbing material to impart a shielding function it is possible to obtain a photosensitive resin composition that has dispersion stability in varnish, can reduce aggregates in a film, and further can form a fine pattern, and have completed the present invention.

That is, the present invention is a photosensitive resin composition including a silicone skeleton-containing polymer (A), an anthraquinone-based dye (B), and a photoacid generator (C).

Hereinafter, the present invention will be described in detail, but the present invention is not limited thereto.

### [(A) Silicone Skeleton-Containing Polymer]

The component (A) silicone skeleton-containing polymer is not particularly limited but preferably contains repeating units represented by the following formulae (a1) to (a4) and (b1) to (b4) (hereinafter, for convenience, also referred to as repeating units a1 to a4 and b1 to b4, respectively).

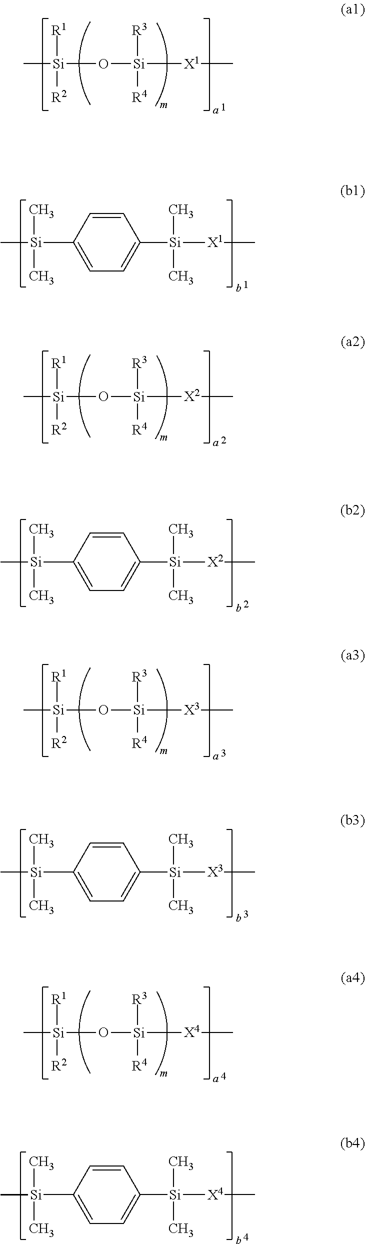

In the formulae (a1) to (a4), R¹ to R⁴ each independently represent a monovalent hydrocarbon group having 1 to 8 carbon atoms. “m” represents an integer of 1 to 600. When “m” is an integer of 2 or more, R³ each may be the same as or different from each other, and R⁴ each may be the same as or different from each other. When there are two or more siloxane units in the repeating units a1 to a4, the siloxane units may all be the same, or may contain two or more different types of siloxane units. When two or more different types of siloxane units are contained (i.e., when “m” is an integer of 2 or more), the siloxane units may be bonded randomly or alternately, or may contain multiple blocks of the same type of siloxane units.

The above monovalent hydrocarbon group may be linear, branched, or cyclic, and specific examples thereof include alkyl groups such as a methyl group, an ethyl group, a propyl group, a hexyl group, a cyclohexyl group, and structural isomers thereof, and aryl groups such as a phenyl group. Among them, a methyl group and a phenyl group are preferable because they are readily available materials.

In the formulae (a1) to (a4), “m” represents an integer of 1 to 600, preferably 1 to 400, and more preferably 1 to 200. When in the range of 1 to 600, flexibility can be imparted to make it easy to form a film, so it is preferable.

In the formulae (a1) to (b1), X¹ represents a divalent group represented by the following formula (X1)

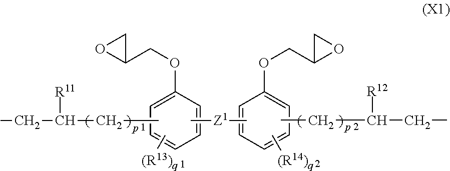

In the formula (X1), Z¹ represents a single bond, a methylene group, a propane-2,2-diyl group, a 1,1,1,3,3,3-hexafluoropropane-2,2-diyl group, or a fluorene-9,9-diyl group. R¹¹ and R¹² each independently represent a hydrogen atom or a methyl group. R¹³ and R¹⁴ each independently represent an alkyl group having 1 to 4 carbon atoms or an alkoxy group having 1 to 4 carbon atoms. p¹ and p² each independently represent an integer of 0 to 7. q¹ and q² each independently represent an integer of 0 to 2.

The alkyl group may be linear, branched, or cyclic, and specific examples thereof include a methyl group, an ethyl group, a propyl group, a butyl group, and structural isomers thereof. The above alkoxy group may be linear, branched, or cyclic, and specific examples thereof include a methoxy group, an ethoxy group, a propoxy group, a butoxy group, and structural isomers thereof.

In the formulae (a2) and (b2), X² represents a divalent group represented by the following formula (X2).

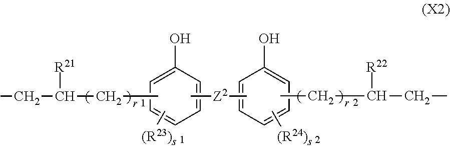

In the formula (X2), Z² represents a single bond, a methylene group, a propane-2,2-diyl group, a 1,1,1,3,3,3-hexafluoropropane-2,2-diyl group, or a fluorene-9,9-diyl group. R²¹ and R²² each independently represent a hydrogen atom or a methyl group. R²³ and R²⁴ each independently represent an alkyl group having 1 to 4 carbon atoms or an alkoxy group having 1 to 4 carbon atoms. r¹ and r² each independently represent an integer of 0 to 7. s¹ and s² each independently represent an integer of 0 to 2. The examples of the alkyl group and the alkoxy group include the same described above.

In the formulae (a3) and (b3), X³ represents a divalent group represented by the following formula (X3).

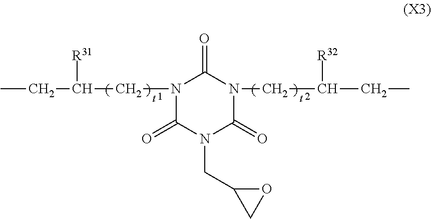

In the formula (X3), R³¹ and R³² each independently represent a hydrogen atom or a methyl group. t¹ and t² each independently represent an integer of 0 to 7.

In the formulae (a4) and (b4), X⁴ represents a divalent group represented by the following formula (X4).

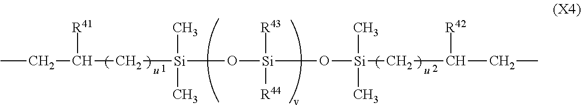

In the formula (X4), R⁴¹ and R⁴² each independently represent a hydrogen atom or a methyl group. R⁴³ and R⁴⁴ each independently represent a monovalent hydrocarbon group having 1 to 8 carbon atoms. u¹ and u² each independently represent an integer of 0 to 7. “v” represents an integer of 0 to 600, preferably 0 to 400, and more preferably 0 to 200. When within the range of 0 to 600, flexibility can be imparted and it becomes easier to form a film, so that it is preferable. Examples of the monovalent hydrocarbon group include the same as those described in the explanation of R¹ to R⁴ above. In the group represented by formula (X4), when “v” is an integer of 2 or more, the siloxane units subscripted by “v” may be randomly bonded or alternately bonded, and may contain multiple blocks of the same type of siloxane units.

The component (A) silicone skeleton-containing polymer preferably has a weight-average molecular weight (Mw) of 3,000 to 500,000, more preferably 5,000 to 200,000. Incidentally, in the present invention, Mw is a value measured in terms of polystyrene by gel permeation chromatography (GPC) using tetrahydrofuran as an elution solvent.

In the formulae (a1) to (a4) and (b1) to (b4), a¹ to a⁴ and b1 to b4 represent numbers satisfying 0≤a¹<1, 0≤a²<1, 0≤a³<1, 0≤a⁴<1, 0≤b¹<1, 0≤b²<1, 0≤b³<1, 0≤b⁴<1, 0<a¹+a²+a³+a⁴<1, 0<b¹+b²+b³+b⁴<1, and a¹+a²+a³+a⁴+b¹+b²+b³+b⁴=1. They are preferably the numbers satisfying 0≤a¹≤0.8, 0≤a²≤0.8, 0≤a³≤0.8, 0≤a⁴≤0.8, 0≤b¹≤0.95, 0≤b²≤0.95, 0≤b³≤0.95, 0≤b⁴≤0.95, 0.05≤a¹+a²+a³+a⁴≤0.8, 0.2≤b¹+b²+b³+b⁴≤0.95, and a¹+a²+a³+a⁴+b¹+b²+b³+b⁴=1. They are more preferably the numbers satisfying 0≤a¹≤0.7, 0≤a²≤0.7, 0≤a³≤0.7, 0≤a⁴≤0.7, 0≤b¹≤0.9, 0≤b²≤0.9, 0≤b³≤0.9, 0≤b⁴≤0.9, 0.1≤a¹+a²+a³+a⁴≤0.7, 0.3≤b¹+b²+b³+b⁴≤0.9, and a¹+a²+a³+a⁴+b¹+b²+b³+b⁴=1.

The component (A) silicone skeleton-containing polymer preferably have a crosslinking group such as an epoxy group and a hydroxy group, or a reactive site generating crosslinking reaction in its molecule. That is, the polymer preferably includes at least one selected from repeating units (a1) to (a3) and at least one selected from repeating units (b1) to (b3). Here, in the formulae (a1) to (a4) and (b1) to (b4), a1 to a4 and b1 to b⁴ are preferably numbers satisfying, 0≤a¹≤1, 0≤a²≤1, 0≤a³≤1, 0≤a⁴≤1, 0≤b¹≤1, 0≤b²≤1, 0≤b³≤1, 0≤b⁴≤1, 0≤a¹+a²+a³≤1, 0≤b¹+b²+b³≤1, and a¹+a²+a³+a⁴+b¹+b²+b³+b⁴=1. They are more preferably numbers satisfying 0≤a¹≤0.8, 0≤a²≤0.8, 0≤a³≤0.8, 0≤a⁴≤0.8, 0≤b¹≤0.95, 0≤b²≤0.95, 0≤b³≤0.95, 0≤b⁴≤0.95, 0.05≤a¹+a²+a³≤0.8, 0.2≤b¹+b²+b³≤0.95, and a¹+a²+a³+a⁴+b¹+b²+b³+b⁴=1. They are further preferably numbers satisfying 0≤a¹≤0.7, 0≤a²≤0.7, 0≤a³≤0.7, 0≤a⁴≤0.7, 0≤b¹≤0.9, 0≤b²≤0.9, 0≤b³≤0.9, 0≤b⁴≤0.9, 0.1≤a¹+a²+a³≤0.7, 0.3≤b¹+b²+b³≤0.9, and a¹+a²+a³+a⁴+b¹+b²+b³+b⁴=1.

Especially, the component (A) silicone skeleton-containing polymer preferably have repeating units a3 and b3. Here, in the formulae (a1) to (a4) and (b1) to (b4), a¹ to a⁴ and b¹ to b⁴ are preferably numbers satisfying 0≤a¹<1, 0≤a²<1, 0≤a³<1, 0≤a⁴<1, 0≤b¹<1, 0≤b²<1, 0<b³<1, 0≤b⁴<1, 0<a¹+a²+a³+a⁴<1, 0<b¹+b²+b³+b⁴<1, and a¹+a²+a³+a⁴+b¹+b²+b³+b⁴=1. They are more preferably numbers satisfying 0≤a¹<0.8, 0≤a²<0.8, 0≤a³<0.8, 0≤a⁴<0.8, 0≤b¹<0.95, 0≤b²<0.95, 0≤b³<0.95, 0≤b⁴<0.95, 0.05≤a¹+a²+a³+a⁴≤0.8, 0.2≤b¹+b²+b³+b⁴≤0.95, and a¹+a²+a³+a⁴+b¹+b²+b³+b⁴=1. They are further preferably numbers satisfying 0≤a¹<0.7, 0≤a²<0.7, 0≤a³<0.7, 0≤a⁴<0.7, 0≤b¹<0.9, 0≤b²<0.9, 0≤b³<0.9, 0≤b⁴<0.9, 0.1≤a¹+a²+a³+a⁴≤0.7, 0.3≤b¹+b²+b³+b⁴≤0.9, and a¹+a²+a³+a⁴+b¹+b²+b³+b⁴=1.

The aforementioned repeating units may bond at random or may bond as a block polymer. Further, siloxane units in each repeating unit may bond at random or may contain a plurality of blocks of the same kind of siloxane. The silicone (siloxane unit) content ratio is preferably 30 to 80 mass % in the silicone resin.

The composition (A) silicone skeleton-containing polymer functions to impart film formability. An obtained resin film has good adhesiveness to laminates, substrates, etc., good patternability, good crack resistance, and good heat resistance.

One kind of the composition (A) silicone skeleton-containing polymer may be used alone or two or more kind thereof may be used in combination.

### [Manufacturing Method of Silicone Skeleton-Containing Polymer]

The composition (A) silicone skeleton-containing polymer can be manufactured by addition polymerization, in the presence of a metal catalyst, of a compound represented by the following formula (1) (hereinafter, also referred to as compound (1)), a compound represented by the following formula (2) (hereinafter, also referred to as compound (2)), and at least one compound selected from a compound represented by the following formula (3) (hereinafter, also referred to as compound (3)), a compound represented by the following formula (4) (hereinafter, also referred to as compound (4)), a compound represented by the following formula (5) (hereinafter, also referred to as compound (5)), and a compound represented by the following formula (6) (hereinafter, also referred to as compound (6)).

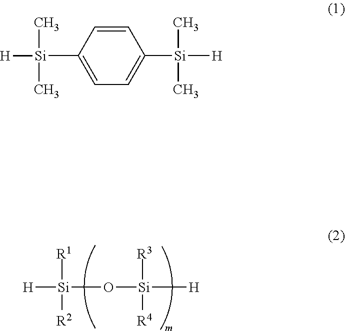

In the formulae, R¹ to R⁴ and “m” is the same as described above.

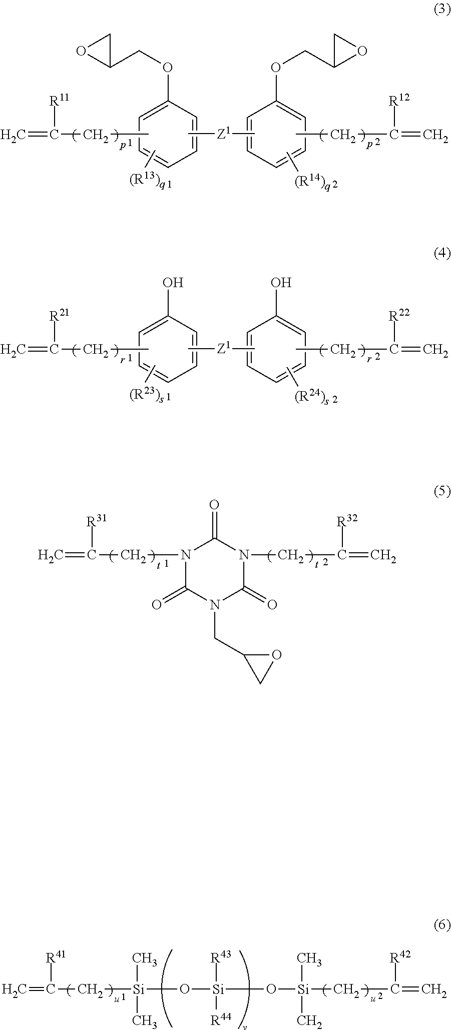

In the formulae, R¹¹ to R¹⁴, R²¹ to R²⁴, R³¹, R³², R⁴¹ to R⁴⁴, Z¹, Z², p¹, p², q¹, q², r¹, r², S¹, S², t¹, t², u¹, u², and “v” are the same as described above.

As the metal catalyst, it is possible to use: simple substance of platinum group metals such as platinum (including platinum black), rhodium, and palladium; platinum chloride, chloroplatinic acid and chloroplatinates such as H₂PtCl₄·xH₂O, H₂PtCl₆·xH₂O, NaHPtCl₆·xH₂O, KHPtCl₆·xH₂O, Na₂PtCl₆·xH₂O, K2PtCl₄·xH₂O, PtCl₄·xH₂O, PtCl₂, Na₂HPtCl₄·xH₂O (here, “x” is preferably an integer of 0 to 6, especially preferably 0 or 6); alcohol-modified chloroplatinic acid (e.g., those described in Specification of U.S. Pat. No. 3,220,972A); complex of chloroplatinic acid and olefin (e.g., those described in Specifications of U.S. Pat. Nos. 3,159,601A, 3,159,662A, and 3,775,452A); platinum group metals such as platinum black and palladium supported on a carrier such as alumina, silica, and carbon; rhodium-olefin complex; chloro tris(triphenylphosphine)rhodium (so-called Wilkinson catalyst); complexes of platinum chloride, chloroplatinic acid, or chloroplatinate with vinyl group-containing siloxanes (especially, vinyl group-containing cyclic siloxanes); etc.

The amount of the above catalyst used is a catalyst mount, generally, preferably in an amount of 0.001 to 0.1 parts by mass, more preferably 0.01 to 0.1 parts by mass relative to 100 parts by mass of sum of compounds (1) to (6).

In the addition polymerization, a solvent may be used as necessary. The solvent is, for example, preferably hydrocarbon solvents such as toluene and xylene.

The addition polymerization is preferably performed preferably at a temperature of 40 to 150° C. in light of preventing catalyst deactivation and enabling short time completion of the polymerization, and more preferably 60 to 120° C. The duration for the addition polymerization depends on a type and an amount of resin to be obtained, but is preferably about 0.5 to 100 hours, more preferably 0.5 to 30 hours, in order to avoid intervention of moisture in the addition polymerization system. When a solvent is used, by the distillation of the solvent after completion of the reaction, the composition (A) silicone skeleton-containing polymer can be obtained.

A method of the reaction is not particularly limited. Examples of the method include: first at least one compound selected from the above compounds (3) to (6) is heated; a metal catalyst is added thereto; and then the above compounds (1) and (2) were added dropwise over 0.1 to 5 hours.

Each of material compounds is preferably blended so that a ratio of sum of hydrosilyl groups contained in the above compounds (1) and (2) is 0.67 to 1.67, more preferably 0.83 to 1.25 in terms of mole ratio relative to sum of alkenyl groups contained in at least one compound selected from the above compounds (3) to (6).

Mw of the component (A) silicone skeleton-containing polymer can be controlled by using a monoallyl compounds such as o-allylphenol, monohydrosilanes such as triethylhydrosilane, or monohydrosiloxanes, as a molecular weight regulator.

### [(B) Anthraquinone-Based Dye]

The component (B) anthraquinone-based dye is not particularly limited.

The component (B) anthraquinone-based dye to be blended in the inventive photosensitive resin composition is not particularly limited, but specifically it is possible using the following. Examples thereof include 2-anilino-1,3,4-trifluoroanthraquinone, (2) 2-(o-ethoxycarbonylanilino)-1,3,4-trifluoroanthraquinone, (3) 2-(p-ethoxycarbonylanilino)-1,3,4-trifluoroanthraquinone, (4) 2-(m-ethoxycarbonylanilino)-1,3,4-trifluoroanthraquinone, (5) 2-(o-cyanoanilino)-1,3,4-trifluoroanthraquinone, (6) 2-(p-cyanoanilino)-1,3,4-trifluoroanthraquinone, (7) 2-(m-cyanoanilino)-1, 3,4-trifluoroanthraquinone, (8) 2-(o-nitroanilino)-1,3,4-trifluoroanthraquinone, (9) 2-(p-nitroanilino)-1,3,4-trifluoroanthraquinone, (10) 2-(m-nitroanilino)-1,3,4-trifluoroanthraquinone, (11) 2-(p-tert-butylanilino)-1,3,4-trifluoroanthraquinone, (12) 2-(o-methoxyanilino)-1,3,4-trifluoroanthraquinone, (13) 2-(2,6-diisopropylanilino)-1,3,4-trifluoroanthraquinone, (14) 2-(2,6-dichloroanilino)-1,3,4-trifluoroanthraquinone, (15) 2-(2,6-difluoroanilino)-1,3,4-trifluoroanthraquinone, (16) 2-(3,4-dicyanoanilino)-1,3,4-trifluoroanthraquinone, (17) 2-(2,4,6-trichloroanilino)-1,3,4-trifluoroanthraquinone, (18) 2-(2,3,5,6-tetrachloroanilino)-1,3,4-trifluoroanthraquinone, (19) 2-(2,3,5,6-tetrafluoroanilino)-1,3, 4-trifluoroanthraquinone, (20) 3-(2,3,4,5-tetrafluoroanilino)-2-butoxy-1,4-difluoroanthraquinone, (21) 3-(4-cyano-3-chloroanilino)-2-octyloxy-1,4-difluoroanthraquinone, (22) 3-(3,4-dicyanoanilino)-2-hexyloxy-1,4-difluoroanthraquinone, (23) 3-(4-cyano-3-chloroanilino)-1,2-dibutoxy-4-fluoroanthraquinone, (24) 3-(p-cyanoanilino)-2-phenoxy-1,4-difluoroanthraquinone, (25) 3-(p-cyanoanilino)-2-(2,6-diethylphenoxy)-1,4-difluoroanthraquinone, (26) 3-(2,6-dichloroanilino)-2-(2, 6-dichlorophenoxy)-1,4-difluoroanthraquinone, (27) 3-(2,3,5,6-tetrachloroanilino)-2-(2,6-dimethoxyphenoxy)-1,4-difluoroanthraquinone, (28) 2,3-dianilino-1,4-difluoroanthraquinone, (29) 2,3-bis(p-tert-butylanilino)-1,4-difluoroanthraquinone, (30) 2,3-bis(p-methoxyanilino)-1,4-difluoroanthraquinone, (31) 2,3-bis(2-methoxy-6-methylanilino)-1,4-difluoroanthraquinone, (32) 2,3-bis(2,6-diisopropylanilino)-1,4-difluoroanthraquinone, (33) 2,3-bis(2,4,6-trichloroanilino)-1,4-difluoroanthraquinone, (34) 2,3-bis(2,3,5,6-tetrachloroanilino)-1,4-difluoroanthraquinone, (35) 2,3-bis(2,3,5,6-tetrafluoroanilino)-1,4-difluoroanthraquinone, (36) 2,3-bis(p-cyanoanilino)-1-methoxyethoxy-4-fluoroanthraquinone, (37) 2-(2,6-dichloroanilino)-1,3,4-trichloroanthraquinone, (38) 2-(2,3,5,6-tetrafluoroanilino)-1,3,4-trichloroanthraquinone, (39) 3-(2,6-dichloroanilino)-2-(2,6-dichlorophenoxy)-1,4-dichloroanthraquinone, (40) 2-(2,6-dichloroanilino)anthraquinone, (41) 2-(2,3,5,6-tetrafluoroanilino)anthraquinone, (42) 3-(2,6-dichloroanilino)-2-(2,6-dichlorophenoxy)anthraquinone, (43) 2,3-bis(2-methoxy-6-methylanilino)-1,4-dichloroanthraquinone, (44) 2,3-bis(2,6-diisopropylanilino)anthraquinone, (45) 2-butylamino-1,3,4-trifluoroanthraquinone, (46) 1,4-bis(n-butylamino)-2,3-difluoroanthraquinone, (47) 1,4-bis(n-octylamino)-2,3-difluoroanthraquinone, (48) 1,4-bis(hydroxyethylamino)-2,3-difluoroanthraquinone, (49) 1,4-bis(cyclohexylamino)-2,3-difluoroanthraquinone, (50) 1,4-bis(cyclohexylamino)-2-octyloxy-3-fluoroanthraquinone, (51) 1,2,4-tris(2,4-dimethoxyphenoxy-3-fluoroanthraquinone), (52) 2,3-bis(phenylthio)-1-phenoxy-4-fluoroanthraquinone, and (53) 1,2,3,4-tetra(p-methoxyphenoxy)-anthraquinone. One or two or more of these can be used in combination.

For the component (B) anthraquinone-based dye, commercial products can be used. Specific examples thereof include: C.I. Solvent Yellow 117, 163, 167, and 189; C.I. Solvent Orange 77 and 86; C.I. Solvent Red 111, 143, 145, 146, 150, 151, 155, 168, 169, 172, 175, 181, 207, 222, 227, 230, 245, and 247; C.I. Solvent Violet 11, 13, 14, 26, 31, 36, 37, 38, 45, 47, 48, 51, 59, and 60; C.I. Solvent Blue 14, 18, 35, 36, 45, 58, 59, 63, 68, 69, 78, 79, 83, 94, 97, 98, 100, 101, 102, 104, 105, 111, 112, 122, 128, 132, 136, and 139; C.I. Solvent Green 3, 28, 29, 32, and 33; C.I. Acid Red 80; C.I. Acid Green 25, 27, 28, and 41; C.I. Acid Violet 34; C.I. Acid Blue 25, 27, 40, 45, 78, 80, and 112; C.I. Disperse Yellow 51; C.I. Disperse Violet 26 and 27; C.I. Disperse Blue 1, 14, 56, and 60; C.I. Direct Blue 40; C.I. Mordant Red 3 and 11; and C.I. Mordant blue 8.

The component (B) anthraquinone-based dye preferably contains a dye having absorption maximum wavelength of 800 nm or less, preferably 300 to 800 nm. When 800 nm or less, it is preferable because leakage light in the visible light region can be blocked.

The inventive photosensitive resin composition preferably contains 0.01 to 50 parts by mass of the component (B) anthraquinone-based dye relative to 100 parts by mass of the component (A) silicone skeleton-containing resin, more preferably 0.01 to 30 parts by mass, even more preferably from 0.01 to 20 parts by mass, and further preferably from 0.5 to 10 parts by mass. When 0.01 parts by mass or more, it is preferable because it exhibits a light-shielding function against leakage light. When 50 parts by mass or less, it is preferable because poor compatibility and generation of aggregates can be suppressed.

### [(C) Photoacid Generator]

The component (C) photoacid generator is not particularly limited as long as it is decomposed by light irradiation and generates acid, but the photoacid generator is preferably to generate acid by irradiating light having a wavelength of 190 to 500 nm. Because the composition used in the present invention is excellent in compatibility with an acid generator, a wide variety of acid generators can be used.

The component (C) photoacid generator is used as a curing catalyst. Examples of the photoacid generator include an onium salt, a diazomethane derivative, a glyoxime derivative, a β-ketosulfone derivative, a disulfone derivative, a nitrobenzylsulfonate derivative, a sulfonic ester derivative, an imido-yl-sulfonate derivative, an oxime sulfonate derivative, an iminosulfonate derivative, and a triazine derivative.

Examples of the above onium salt include a sulfonium salt represented by the following formula (C1) and an iodonium salt represented by the following formula (C2).

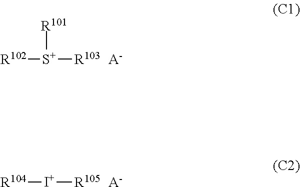

In the above formulae (C1) and (C2), R¹⁰¹ to R¹⁰⁵ each independently represent: an alkyl group having 1 to 12 carbon atoms, which may have a substituent; an aryl group having 6 to 12 carbon atoms, which may have a substituent; or an aralkyl group having 7 to 12 carbon atoms, which may have a substituent. A⁻ is a non-nucleophilic counter ion.

The above alkyl group may be linear, branched, or cyclic. Specific examples thereof include a methyl group, an ethyl group, an n-propyl group, an isopropyl group, a cyclopropyl group, an n-butyl group, an isobutyl group, a sec-butyl group, a tert-butyl group, a cyclobutyl group, an n-pentyl group, a cyclopentyl group, a cyclohexyl group, a norbornyl group, and an adamantyl group. Examples of the aryl group include a phenyl group, a naphthyl group, and a biphenylyl group. Examples of the above aralkyl group include a benzyl group and a phenethyl group.

The examples of the substituent include an oxo group, a linear, branched, or cyclic alkoxy group having 1 to 12 carbon atoms, a linear, branched, or cyclic alkyl group having 1 to 12 carbon atoms, an aryl group having 6 to 24 carbon atoms, an aralkyl group having 7 to 25 carbon atoms, an aryloxy group having 6 to 24 carbon atoms, and an arylthio group having 6 to 24 carbon atoms.

R¹⁰¹ to R¹⁰⁵ is preferably; alkyl groups, which may have a substituent, such as a methyl group, an ethyl group, a propyl group, a butyl group, a cyclohexyl group, a norbornyl group, an adamantyl group, and a 2-oxocyclohexyl group; an aryl groups, which may have a substituent, such as a phenyl group, a naphthyl group, a biphenylyl group, an o-, m- or p-methoxyphenyl group, an ethoxyphenyl group, an m- or p-tert-butoxyphenyl group, a 2-, 3- or 4-methylphenyl group, an ethylphenyl group, a 4-tert-butylphenyl group, 4-butylphenyl group, a dimethylphenyl group, a terphenylyl group, a biphenylyloxyphenyl group, and a biphenylylthiophenyl group; aralkyl groups, which may have a substituent, such as a benzyl group and a phenethyl group. Among these, an aryl group that may have a substituent and an aralkyl group that may have a substituent are more preferable.

Examples of the above non-nucleophilic counter ion A⁻ include halide ions such as a chloride ion and a bromide ion; fluoroalkanesulfonate ions such as a triflate ion, a 1,1,1-trifluoroethanesulfonate ion, and a nonafluorobutanesulfonate ion; aryl sulfonate ions such as a tosylate ion, a benzenesulfonate ion, a 4-fluorobenzenesulfonate ion, and a 1,2,3,4,5-pentafluorobenzenesulfonate ion; alkanesulfonate ions such as a mesylate ion and a butanesulfonate ion; fluoroalkanesulfonimide ions such as a trifluoromethanesulfonimide ion; fluoroalkanesulfonylmethide ions such as a tris(trifluoromethanesulfonyl)methide ion; borate ions such as a tetrakis phenylborate ion and a tetrakis(pentafluorophenyl)borate ion.

The above diazomethane derivative includes a compound represented by the following formula (C3).

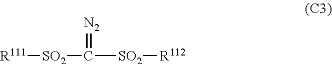

In the formula (C3), R¹¹¹ and R¹¹² are each independently an alkyl or halogenated alkyl group having 1 to 12 carbon atoms, an aryl group, which may have a substituent, having 6 to 12 carbon atoms, or an aralkyl group having 7 to 12 carbon atoms.

The above alkyl group may be linear, branched, or cyclic, and specific examples include the same as exemplified in description for R¹⁰¹ to R¹⁰⁵. The halogenated alkyl group include a trifluoromethyl group, a 1,1,1-trifluoroethyl group, a 1,1,1-trichloroethyl group, and a nonafluorobutyl group.

Examples of the above aryl group that may have a substituent include: a phenyl group; alkoxyphenyl groups such as a 2-, 3- or 4-methoxyphenyl group, a 2-, 3- or 4-ethoxyphenyl group, and a 3- or 4-tert-butoxyphenyl group; alkylphenyl groups such as a 2-, 3- or 4-methylphenyl group, an ethylphenyl group, a 4-tert-butylphenyl group, a 4-butylphenyl group, and a dimethylphenyl group; halogenated aryl groups such as a fluorophenyl group, a chlorophenyl group, and a 1,2,3,4,5-pentafluorophenyl group. Examples of the above aralkyl group include a benzyl group and a phenethyl group.

The glyoxime derivatives include compounds represented by the following formula (C4).

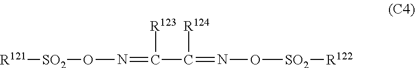

In the above formula (C4), R¹²¹ to R¹²⁴ is each independently an alkyl group or halogenated alkyl group having 1 to 12 carbon atoms, an aryl group, which may have a substituent, having 6 to 12 carbon atoms, or an aralkyl group having 7 to 12 carbon atoms. Further, R¹²³ and R¹²⁴ may bond each other to form a ring together with the carbon atoms bonded to these. When forming a ring, a group formed by bonding of R¹²³ and R¹²⁴ is a linear or branched alkylene group having 1 to 12 carbon atoms.

Examples of the above alkyl group, the above halogenated alkyl group, the above aryl group that may have a substituent, and the above aralkyl group include the same as exemplified for R¹¹¹ and R¹¹². The above linear or branched alkylene groups include a methylene group, an ethylene group, a propylene group, a butylene group, and a hexylene group.

Specific examples of the above onium salt include diphenyliodonium trifluoromethanesulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethanesulfonate, bis(p-tert-butoxyphenyl)phenylsulfonium trifluoromethane-sulfonate, tris(p-tert-butoxyphenyl)sulfonium trifluoromethane-sulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl)sulfonium p-toluenesulfonate, triphenylsulfonium nonafluorobutanesulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethanesulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, bis(4-tert-butylphenyl)iodonium hexafluorophosphate, diphenyl(4-thiophenoxyphenyl)sulfonium hexafluoroantimonate, [4-(4-biphenylylthio)phenyl]-4-biphenylylphenylsulfonium tris(trifluoromethanesulfonyl)methide, triphenylsulfonium tetrakis(fluorophenyl)borate, tris[4-(4-acetylphenyl)thiophenyl]sulfonium tetrakis(fluorophenyl)borate, triphenylsulfonium tetrakis(pentafluorophenyl)borate, and tris[4-(4-acetylphenyl)thiophenyl]sulfonium tetrakis(pentafluorophenyl)borate.

Specific examples of the diazomethane derivative include bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, bis(tert-butylsulfonyl)diazomethane, bis(n-pentylsulfonyl)diazomethane, bis(isopentylsulfonyl)diazomethane, bis(sec-pentylsulfonyl)diazomethane, bis(tert-pentylsulfonyl)diazomethane, 1-cyclohexylsulfonyl-1-(tert-butylsulfonyl)diazomethane, 1-cyclohexylsulfonyl-1-(tert-pentylsulfonyl)diazomethane, and 1-tert-pentylsulfonyl-1-(tert-butylsulfonyl)diazomethane.

Specific examples of the glyoxime derivative include bis-o-(p-toluenesulfonyl)-α-dimethylglyoxime, bis-o-(p-toluenesulfonyl)-α-diphenylglyoxime, bis-o-(p-toluenesulfonyl)-α-dicyclohexylglyoxime, bis-o-(p-toluenesulfonyl)-2,3-pentanedioneglyoxime, bis-(p-toluenesulfonyl)-2-methyl-3,4-pentanedioneglyoxime, bis-o-(n-butanesulfonyl)-α-dimethylglyoxime, bis-o-(n-butanesulfonyl)-α-diphenylglyoxime, bis-o-(n-butanesulfonyl)-α-dicyclohexylglyoxime, bis-o-(n-butanesulfonyl)-2,3-pentanedioneglyoxime, bis-o-(n-butanesulfonyl)-2-methyl-3,4-pentanedioneglyoxime, bis-o-(methanesulfonyl)-α-dimethylglyoxime, bis-o-(trifluoromethanesulfonyl)-α-dimethylglyoxime, bis-o-(1,1,1-trifluoroethanesulfonyl)-α-dimethylglyoxime, bis-o-(tert-butanesulfonyl)-α-dimethylglyoxime, bis-o-(perfluorooctanesulfonyl)-α-dimethylglyoxime, bis-o-(cyclohexanesulfonyl)-α-dimethylglyoxime, bis-o-(benzenesulfonyl)-α-dimethylglyoxime, bis-o-(p-fluorobenzenesulfonyl)-α-dimethylglyoxime, bis-o-(p-tert-butylbenzenesulfonyl)-α-dimethylglyoxime, bis-o-(xylenesulfonyl)-α-dimethylglyoxime, and bis-o-(camphorsulfonyl)-α-dimethylglyoxime.

Specific examples of the β-ketosulfone derivative include 2-cyclohexylcarbonyl-2-(p-toluenesulfonyl)propane and 2-isopropylcarbonyl-2-(p-toluenesulfonyl)propane.

Specific examples of the above disulfone derivative include diphenyldisulfone and dicyclohexyldisulfone.

Specific examples of the above nitrobenzylsulfonate derivative include 2,6-dinitrobenzyl p-toluenesulfonate and 2,4-dinitrobenzyl p-toluenesulfonate.

Specific examples of the above sulfonic ester derivative include 1,2,3-tris(methanesulfonyloxy)benzene, 1,2,3-tris(trifluoromethanesulfonyloxy)benzene, and 1,2,3-tris(p-toluenesulfonyloxy)benzene.

Specific example of the above imido-yl-sulfonate derivatives include phthalimido-yl-triflate, phthalimido-yl-tosylate, 5-norbornene-2,3-dicarboximido-yl-triflate, 5-norbornene-2,3-dicarboximido-yl-tosylate, 5-norbornene-2,3-dicarboximido-yl-n-butylsulfonate, and n-trifluoromethylsulfonyloxynaphthylimide.

Specific examples of the above oxime sulfonate derivative include α-(benzenesulfoniumoxyimino)-4-methylphenylacetonitrile.

Specific examples of the above iminosulfonate derivative include (5-(4-methylphenyl)sulfonyloxyimino-5H-thiophen-2-ylidene)-(2-methylphenyl)acetonitrile and (5-(4-(4-methylphenylsulfonyloxy)phenylsulfonyloxyimino)-5H-thiophen-2-ylidene)-(2-methylphenyl)-acetonitrile.

Specific example of the above triazine derivatives include 2-(methoxyphenyl)-4,6-bis(trichloromethyl)-s-triazine, 2-[2-(3,4-dimethoxyphenyl)ethenyl]-4,6-bis(trichloromethyl)-s-triazine, 2-[2-(furan-2-yl)ethenyl]-4,6-bis(trichloromethyl)-s-triazine, and 2-[2-(5-methylfuran-2-yl)ethenyl]-4,6-bis(trichloromethyl)-s-triazine.

Further, 2-methyl-2-[(4-methylphenyl)sulfonyl]-1-[(4-methylthio)phenyl]-1-propane, etc. can also be suitably used.

As the component (C) photoacid generator, the above onium salts are preferable and the above sulfonium salts are more preferable.

In terms of photo curability, the component (C) is contained preferably 0.05 to 20 parts by mass, more preferably 0.05 to 5 parts by mass, relative to 100 parts by mass of the component (A). When the component (C) is contained in an amount of 0.05 parts by mass or more, it is preferable because sufficient amount of acid is generated to allow the crosslinking reaction to proceed sufficiently. When the component (C) is contained in an amount of 20 parts by mass or less, it is preferable because increased absorbance of the photoacid generator itself can be suppressed and its transparency is sufficient. One kind of the component (C) may be used alone, or two or more kinds may be used in combination.

The inventive photosensitive resin composition preferably further includes any one or more of a crosslinking agent (D), a solvent (E), a quencher (F), and an antioxidant (G), in addition to the silicone skeleton-containing polymer (A), the anthraquinone-based dye (B), and the photoacid generator (C).

### [(D) Crosslinking Agent]

The component (D) crosslinking agent causes a condensation reaction with a phenolic hydroxy group or with an alkoxy group represented by R¹³, R¹⁴, R²³ or R²⁴ of the aforementioned component (A), is a component to make patterning easy, and increases the strength of a cured product further.

The above component (D) crosslinking agent is preferably a resin having Mw of 150 to 10,000, especially Mw of 200 to 3,000. When Mw is 150 or more, sufficient photo curability can be obtained. When Mw is 10,000 or less, it is preferable because there is no risk of deteriorating heat-resistance of cured composition.

The above component (D) crosslinking agent is preferably: a melamine compound having two or more methylol groups and/or alkoxymethyl groups on average in one molecule; a nitrogen-containing compound such as a guanamine compound a glycoluril compound, and an urea compound; amino condensates modified with a formaldehyde or formaldehyde-alcohol; a phenolic compound having two or more methylol groups and/or alkoxymethyl groups on average in one molecule; and an epoxy compound having two or more epoxy groups on average in one molecule.

The melamine compounds include a compound represented by the following formula (D1).

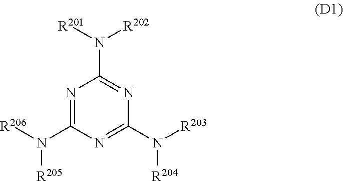

In the formula (D1), R²⁰¹ to R²⁰⁶ each independently represent a methylol group, an alkoxymethyl group having 2 to 5 carbon atoms, or a hydrogen atom, but at least one of them is a methylol group or an alkoxymethyl group. The alkoxymethyl groups include a methoxymethyl group and an ethoxymethyl group.

Examples of the melamine compound represented by the formula (D1) include trimethoxymethylmonomethylolmelamine, dimethoxymethylmonomethylolmelamine, trimethylolmelamine, hexamethylolmelamine, and hexamethoxymethylmelamine, hexaethoxymethylmelamine.

The melamine compound represented by the formula (D1) can be obtained, for example, by first methylolating a melamine monomer with formaldehyde according to a publicly known method, or by further alkoxylating this compound with alcohol. The alcohol is preferably lower alcohol, for example, alcohol having 1 to 4 carbon atoms.

Examples of the guanamine compound include tetramethylolguanamine, tetramethoxymethylguanamine, and tetramethoxyethylguanamin.

Examples of the glycoluril compound include tetramethylol glycoluril and tetrakis(methoxymethyl)glycoluril.

Example of the urea compound include tetramethylolurea, tetramethoxymethylurea, tetramethoxyethylurea, tetraethoxymethylurea, and tetrapropoxymethylurea.

Examples of the formaldehyde or formaldehyde-alcohol modified amino condensate include formaldehyde or formaldehyde-alcohol modified melamine condensates and formaldehyde and formaldehyde-alcohol modified urea condensates.

Examples of the modified melamine condensates include a compound obtained by addition condensation polymerization of a compound represented by formula (D1) or a multimer thereof (e.g., oligomers such as dimers and trimers) and formaldehyde according to conventional methods until a desired molecular weight is reached.

Example of the formaldehyde or formaldehyde-alcohol modified urea condensates include a methoxymethylated urea condensate, an ethoxymethylated urea condensate, and a propoxymethylated urea condensate.

The modified urea condensates can be obtained, for example, by methylolating a urea condensate having a desired molecular weight with formaldehyde according to a publicly known method, or by further alkoxylating this compound with alcohol.

Examples of the phenolic compound having on average two or more methylol groups or alkoxymethyl groups in one molecule include (2-hydroxy-5-methyl)-1,3-benzenedimethanol and 2,2′,6,6′-tetramethoxymethylbisphenol A.

Examples of the epoxy compound having on average two or more epoxy groups in one molecule include: bisphenol type epoxy resins such as bisphenol A type epoxy resin and bisphenol F type epoxy resin; novolac type epoxy resins such as phenol novolac type epoxy resin and cresol novolac type epoxy resin; triphenolalkane type epoxy resins; biphenyl type epoxy resins; dicyclopentadiene-modified phenol novolac type epoxy resins; phenol aralkyl type epoxy resins; biphenylaralkyl type epoxy resins; naphthalene ring-containing epoxy resins; glycidyl ester type epoxy resins; alicyclic epoxy resins; and heterocyclic epoxy resins.

When the inventive photosensitive resin composition contains the component (D), its content amount is preferably 0.5 to 50 parts by mass, more preferably 1 to 30 parts by mass, relative to 100 parts by mass of the component (A). When 0.5 parts by mass or more, sufficient curability can be obtained by light irradiation. When 50 parts by mass or less, the cured composition can exhibit advantageous effects of the present invention fully because the content ratio of the component (A) in the photosensitive resin composition does not decrease. One kind of the component (D) a crosslinking agent may be used alone or two or more kinds thereof may be used in combination.

### [(E) Solvent]

The component (E) a solvent is not particularly limited, as long as the components (A) to (D) and the additives described later can be solved in the solvent. An organic solvent is preferable because an organic solvent has excellent solubility for these components.

Examples of the organic solvent include: ketones such as cyclohexanone, cyclopentanone, and methyl-2-n-pentyl ketone; alcohols such as 3-methoxybutanol, 3-methyl-3-methoxybutanol, 1-methoxy-2-propanol, and 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, and γ-butyrolactone. One kind of these organic solvents may be used alone, or two or more kinds thereof may be used in combination. Particularly preferred are ethyl lactate, cyclohexanone, cyclopentanone, PGMEA, γ-butyrolactone or a mixed solvent thereof, because these has the best solubility for the photoacid generator.

In terms of compatibility and viscosity of the photosensitive resin composition, the component (E) is preferably used in an amount of 50 to 2,000 parts by mass, more preferably 50 to 1,000 parts by mass, and particularly preferably 50 to 100 parts by mass, relative to 100 parts by mass of sum of the components (A), (B), and (C).

### [(F) Quencher]

As the component (F), a suitable quencher is a compound that can suppress diffusion rate of an acid generated by a photoacid generator in a photosensitive resin film. By blending of such a quencher, it is possible to enhance resolution, suppress a sensitivity change after exposure, reduce substrate dependence or environmental dependence, and improve exposure latitude and a pattern profile.

Examples of the quencher as the component (F) include primary, secondary, or tertiary aliphatic amines, mixed amines, aromatic amines, heterocyclic amines, nitrogen-containing compounds having carboxy groups, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, and imide derivatives.

Examples of the primary aliphatic amines include ammonia, methylamine, ethylamine, n-propylamine, isopropylamine, n-butylamine, isobutylamine, sec-butylamine, tert-butylamine, pentylamine, tert-pentylamine, cyclopentylamine, hexylamine, cyclohexylamine, heptylamine, octylamine, nonylamine, decylamine, dodecylamine, cetylamine, methylenediamine, ethylenediamine, and tetraethylenepentamine.

Examples of the secondary aliphatic amines include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethylmethylenediamine, N,N-dimethylethylenediamine, and N,N-dimethyltetraethylenepentamine.

Examples of the tertiary aliphatic amines include trimethylamine, triethylamine, tri-n-propylamine, triisopropylamine, tri-n-butylamine, triisobutylamine, tri-sec-butylamine, tripentylamine, tricyclopentylamine, trihexylamine, tricyclohexylamine, triheptylamine, trioctylamine, trinonylamine, tridecylamine, tridodecylamine, tricetylamine, N,N,N′,N′-tetramethylmethylenediamine, N,N,N′,N′-tetramethylethylenediamine, and N,N,N′,N′-tetramethyltetraethylenepentamine.

Examples of the mixed amines include dimethylethylamine, methylethylpropylamine, benzylamine, phenethylamine, and benzyldimethylamine.

Examples of the aromatic amines and the heterocyclic amines include aniline derivatives (e.g., aniline, N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, etc.), diphenyl(p-tolyl)amine, methyldiphenylamine, triphenylamine, phenylenediamine, naphthylamine, diaminonaphthalene, pyrrole derivatives (e.g., pyrrole, 2H-pyrrole, 1-methylpyrrole, 2,4-dimethylpyrrole, 2,5-dimethylpyrrole, N-methylpyrrole, etc.), oxazole derivatives (e.g., oxazole, isoxazole, etc.), thiazole derivatives (e.g., thiazole, isothiazole, etc.), imidazole derivatives (e.g., imidazole, 4-methylimidazole, 4-methyl-2-phenylimidazole, etc.), pyrazole derivatives, furazane derivatives, pyrroline derivatives (e.g., pyrroline, 2-methyl-1-pyrroline, etc.), pyrrolidine derivatives (e.g., pyrrolidine, N-methylpyrrolidine, pyrrolidinone, N-methyl-2-pyrrolidone, etc.), imidazoline derivatives, imidazolidine derivatives, pyridine derivatives (e.g., pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-tert-butylpyridine, diphenylpyridine, benzylpyridine, methoxypyridine, butoxypyridine, dimethoxypyridine, 1-methyl-2-pyridine, 4-pyrrolidinopyridine, 1-methyl-4-phenylpyridine, 2-(1-ethylpropyl)pyridine, aminopyridine, dimethylaminopyridine, etc.), pyridazine derivatives, pyrimidine derivatives, pyrazine derivatives, pyrazoline derivatives, pyrazolidine derivatives, piperidine derivatives, piperazine derivatives, morpholine derivatives, indole derivatives, isoindole derivatives, 1H-indazole derivatives, indoline derivatives, quinoline derivatives (e.g., quinoline, 3-quinoline carbonitrile, etc.), isoquinoline derivatives, cinnoline derivatives, quinazoline derivatives, quinoxaline derivatives, phthalazine derivatives, purine derivatives, pteridine derivatives, carbazole derivatives, phenanthridine derivatives, acridine derivatives, phenazine derivatives, 1,10-phenanthroline derivatives, adenine derivatives, adenosine derivatives, guanine derivatives, guanosine derivatives, uracil derivatives, and uridine derivatives.

Examples of the nitrogen-containing compounds having a carboxy group include aminobenzoic acid, indolecarboxylic acid, and amino acid derivatives (e.g., nicotinic acid, alanine, arginine, aspartic acid, glutamic acid, glycine, histidine, isoleucine, glycylleucine, leucine, methionine, phenylalanine, threonine, lysine, 3-aminopyrazine-2-carboxylic acid, methoxyalanine, etc.).

Examples of the nitrogen-containing compounds having a sulfonyl group include 3-pyridine sulfonic acid and pyridinium p-toluenesulfonate.

Examples of the nitrogen-containing compounds having a hydroxy group, the nitrogen-containing compound having a hydroxyphenyl group, and an alcoholic nitrogen-containing compound include 2-hydroxypyridine, aminocresol, 2-quinolinediol, 3-indolemethanol hydrate, monoethanolamine, diethanolamine, triethanolamine, N-ethyldiethanolamine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, 1-[2-(2-hydroxyethoxy)ethyl]piperazine, piperidineethanol, 1-(2-hydroxyethyl)pyrrolidine, 1-(2-hydroxyethyl)-2-pyrrolidinone, 3-piperidino-1,2-propanediol, 3-pyrrolidino-1,2-propanediol, 8-hydroxyeurolidine, 3-quinuclidinol, 3-tropanol, 1-methyl-2-pyrrolidineethanol, 1-aziridineethanol, N-(2-hydroxyethyl)phthalimide, and N-(2-hydroxyethyl)isonicotinamide.

Examples of the amide derivatives include formamide, N-methylformamide, N,N-dimethylformamide, acetamide, N-methylacetamide, N,N-dimethylacetamide, propionamide, and benzamide.

Examples of the imide derivatives include phthalimide, succinimide, and maleimide.

It is possible to use compounds represented by the following formula (F1) also as the component (F) quencher.

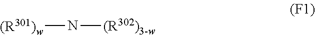

In the formula (F1), “w” represents 1, 2, or 3. R³⁰¹ is any substituent selected form the group consisting of substituents represented by the following formulae (F2) to (F4). R³⁰² is a hydrogen atom or an alkyl group having 1 to 20 carbon atoms, and may have an ether bond or a hydroxy group. When two or more R³⁰¹ exist, two R³⁰¹ may bond each other to form a ring together with a nitrogen atom bonded with R³⁰¹. Further, when two or more R³⁰¹ exist, these may be the same or different. When two or more R³⁰² exist, these may be the same or different.

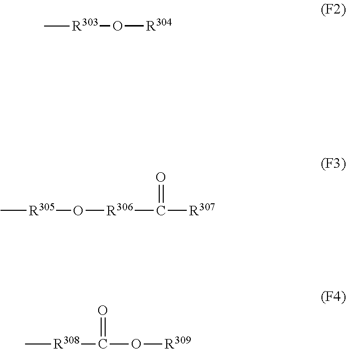

In the formulae (F2) to (F4), R³⁰³, R³⁰⁵, and R³⁰¹ represent each independently a linear or branched alkanediyl group having 1 to 4 carbon atoms. R³⁰⁴ and R³⁰⁷ represent each independently a hydrogen atom or an alkyl group having 1 to 20 carbon atoms, and may have at least one selected from the group consisting of a hydroxy group, an ether bond, an ester bond, and a lactone ring. R³⁰⁶ represents a single bond, or a linear or branched alkanediyl group having 1 to 4 carbon atoms. R³⁰⁹ represents an alkyl group having 1 to 20 carbon atoms, and may have at least one selected from the group consisting of a hydroxy group, an ether bond, an ester bond, and a lactone ring.

Examples of the compounds represented by the formula (F1) include, but is not limited to, tris[2-(methoxymethoxy)ethyl]amine, tris[2-(2-methoxyethoxy)ethyl]amine, tris[2-(2-methoxyethoxymethoxy)ethyl]amine, tris[2-(1-methoxyethoxy)ethyl]amine, tris[2-(1-ethoxyethoxy)ethyl]amine, tris[2-(1-ethoxypropoxy)ethyl]amine, tris[2-{2-(2-hydroxyethoxy)ethoxy}ethyl]amine, 4,7,13,16,21,24-hexaoxa-1,10-diazabicyclo[8.8.8]hexacosane, 4,7,13,18-tetraoxa-1,10-diazabicyclo[8.5.5]eicosane, 1,4,10,13-tetraoxa-7,16-diazabicyclooctadecane, 1-aza-12-crown-4, 1-aza-15-crown-5, 1-aza-18-crown-6, tris(2-formyloxyethyl)amine, tris(2-acetoxyethyl)amine, tris(2-propionyloxyethyl)amine, tris(2-butyryloxyethyl)amine, tris(2-isobutyryl)oxyethyl)amine, tris(2-valeryloxyethyl)amine, tris(2-pivaloyloxyethyl)amine, N,N-bis(2-acetoxyethyl)2-(acetoxyacetoxy)ethylamine, tris(2-methoxycarbonyloxyethyl)amine, tris(2-tert-butoxycarbonyloxyethyl)amine, tris[2-(2-oxopropoxy)ethyl]amine, tris[2-(methoxycarbonylmethyl)oxyethyl]amine, tris[2-(tert-butoxycarbonylmethyloxy)ethyl]amine, tris[2-(cyclohexyloxycarbonylmethyloxy)ethyl]amine, tris(2-methoxycarbonylethyl)amine, tris(2-ethoxycarbonylethyl)amine, N,N-bis(2-hydroxyethyl)-2-(methoxycarbonyl)ethylamine, N,N-bis(2-acetoxyethyl)-2-(methoxycarbonyl)ethylamine, N,N-bis(2-hydroxyethyl)-2-(ethoxycarbonyl)ethylamine, N,N-bis(2-acetoxyethyl)-2-(ethoxycarbonyl)ethylamine, N,N-bis(2-hydroxyethyl)-2-(2-methoxyethoxycarbonyl)ethylamine, N,N-bis(2-acetoxyethyl)-2-(2-methoxyethoxycarbonyl)ethylamine, N,N-bis(2-hydroxyethyl)-2-(2-hydroxyethoxycarbonyl)ethylamine, N,N-bis(2-acetoxyethyl)-2-(2-acetoxyethoxycarbonyl)ethylamine, N,N-bis(2-hydroxyethyl)-2-[(methoxycarbonyl)methoxycarbonyl]ethylamine, N,N-bis(2-acetoxyethyl)-2-[(methoxycarbonyl)methoxycarbonyl]ethylamine, N,N-bis(2-hydroxyethyl)-2-(2-oxopropoxycarbonyl)ethylamine, N,N-bis(2-acetoxyethyl)-2-(2-oxopropoxycarbonyl)ethylamine, N,N-bis(2-hydroxyethyl)-2-(tetrahydrofurfuryloxycarbonyl)ethylamine, N,N-bis(2-acetoxyethyl)-2-(tetrahydrofurfuryloxycarbonyl)ethylamine, N,N-bis(2-hydroxyethyl)-2-[(2-oxotetrahydrofuran-3-yl)oxycarbonyl]ethylamine, N,N-bis(2-acetoxyethyl)-2-[(2-oxotetrahydrofuran-3-yl)oxycarbonyl]ethylamine, N,N-bis(2-hydroxyethyl)-2-(4-hydroxybutoxycarbonyl)ethylamine, N,N-bis(2-formyloxyethyl)-2-(4-formyloxybutoxycarbonyl)ethylamine, N,N-bis(2-formyloxyethyl)-2-(2-formyloxyethoxycarbonyl)ethylamine, N,N-bis(2-methoxyethyl)-2-(methoxycarbonyl)ethylamine, N-(2-hydroxyethyl)bis[2-(methoxycarbonyl)ethyl]amine, N-(2-acetoxyethyl)bis[2-(methoxycarbonyl)ethyl]amine, N-(2-hydroxyethyl)bis[2-(ethoxycarbonyl)ethyl]amine, N-(2-acetoxyethyl)bis[2-(ethoxycarbonyl)ethyl]amine, N-(3-hydroxy-1-propyl)bis[2-(methoxycarbonyl)ethyl]amine, N-(3-acetoxy-1-propyl)bis[2-(methoxycarbonyl)ethyl]amine, N-(2-methoxyethyl)bis[2-(methoxycarbonyl)ethyl]amine, N-butylbis[2-(methoxycarbonyl)ethyl]amine, N-butylbis[2-(2-methoxyethoxycarbonyl)ethyl]amine, N-methylbis(2-acetoxyethyl)amine, N-ethylbis(2-acetoxyethyl)amine, N-methylbis(2-pivaloyloxyethyl)amine, N-ethylbis[2-(methoxycarbonyloxy)ethyl]amine, N-ethylbis[2-(tert-butoxycarbonyloxy)ethyl]amine, tris(methoxycarbonylmethyl)amine, tris(ethoxycarbonylmethyl)amine, N-butylbis(methoxycarbonylmethyl)amine, N-hexylbis(methoxycarbonylmethyl)amine, and β-(diethylamino)-δ-valerolactone.

Content amount of the component (F) is 0 to 3 parts by mass relative to 100 parts by mass of the component (A). When containing the component (F), in view of sensitivity, its content amount is preferably 0.01 to 2 parts by mass, more preferably 0.05 to 1 parts by mass. One kind of the components (F) can be used alone or two or more kinds thereof may be used in combination.

### [(G) Antioxidant]

By including the component (G) antioxidant, it is possible to improve heat-resistance and makes it further easier to obtain transparency of a photosensitive resin composition. Examples of the component (G) antioxidant include a hindered phenolic compound, ammonia, a primary aliphatic amine, and a hindered amine compound.

The above hindered phenolic compounds are not particularly limited, but the following are preferable. Examples thereof include, 1,3,5-trimethyl-2,4,6-tris(3,5-di-tert-butyl-4-hydroxybenzyl)benzene (product name: Irganox 1330), 2,6-di-tert-butyl-4-methylphenol (product name: Sumilizer BHT), 2,5-di-tert-butyl-hydroquinone (product name: Nocrac NS-7), 2,6-di-tert-butyl-4-ethylphenol (Product name: Nocrac M-17), 2,5-di-tert-pentylhydroquinone (Product name: Nocrac DAH), 2,2′-methylenebis(4-methyl-6-tert-butylphenol) (Product name: Nocrac NS-6), 3,5-di-tert-butyl-4-hydroxy-benzylphosphonate-diethyl ester (product name: Irganox 1222), 4,4′-thiobis(3-methyl-6-tert-butylphenol) (Product name: Nocrac 300), 2,2′-methylenebis(4-ethyl-6-tert-butylphenol) (Product name: Nocrac NS-5), 4,4′-butylidenebis(3-methyl-6-tert-butylphenol) (product name: ADK STAB AO-40), 2-tert-butyl-6-(3-tert-butyl-2-hydroxy-5-methylbenzyl)-4-methylphenylacrylate (product name: Sumilizer GM), 2-[1-(2-hydroxy-3,5-di-tert-pentylphenyl)ethyl]-4,6-di-tert-pentylphenyl acrylate (product name: Sumilizer GS), 2,2′-methylenebis[4-methyl-6-(a-methyl-cyclohexyl)phenol], 4,4′-methylenebis(2,6-di-tert-butylphenol) (product name: SEENOX 226M), 4,6-bis(octylthiomethyl)-o-cresol (product name: Irganox 1520L), 2,2′-ethylenebis(4,6-di-tert-butylphenol), octadecyl-3-(3,5-di-tert-butyl-4-hydroxyphenyl)propionate (product name: Irganox 1076), 1,1,3-tris-(2-methyl-4-hydroxy-5-tert-butylphenyl)butane (product name: ADK STAB AO-30), tetrakis[methylene-(3,5-di-tert-butyl-4-hydroxyhydrocinnamate)]methane (product name: ADK STAB AO-60), triethylene glycol bis[3-(3-tert-butyl-5-methyl-4-hydroxyphenyl)propionate](product name: Irganox 245), 2,4-bis-(n-octylthio)-6-(4-hydroxy-3,5-di-tert-butylanilino)-1,3,5-triazine (product name: Irganox 565), N,N′-hexamethylenebis(3,5-di-tert-butyl-4-hydroxy-hydrocinnamamide) (product name: Irganox 1098), 1,6-hexanediol-bis[3-(3,5-di-tert-butyl-4-hydroxyphenyl)propionate](product name: Irganox 259), 2,2-thio-diethylenebis[3-(3,5-di-tert-butyl-4-hydroxyphenyl)propionate](product name: Irganox 1035), 3,9-bis[2-[3-(3-tert-butyl-4-hydroxy-5-methylphenyl)propionyloxy]1,1-dimethylethyl]2,4,8,10-tetraoxaspiro[5.5]undecane (product name: Sumilizer GA-80), tris-(3,5-di-tert-butyl-4-hydroxybenzyl)isocyanurate (product name: Irganox 3114), bis(3,5-di-tert-butyl-4-hydroxybenzylethylphosphonate) calcium/polyethylene wax mixture (50:50) (product name: Irganox 1425WL), isooctyl-3-(3,5-di-tert-butyl-4-hydroxyphenyl)propionate (product name: Irganox 1135), 4,4′-thiobis(6-tert-butyl-3-methylphenol) (product name: Sumilizer WX-R), and 6-[3-(3-tert-butyl-4-hydroxy-5-methylphenyl)propoxy]-2,4,8,10-tetra-tert-butyldibenz[d,f][1,3,2]dioxaphosphepine (product name: Sumilizer GP).

Examples of the above primary aliphatic amines include methylamine, ethylamine, n-propylamine, isopropylamine, n-butylamine, isobutylamine, sec-butylamine, tert-butylamine, pentylamine, tert-pentylamine, cyclopentylamine, hexylamine, cyclohexylamine, heptylamine, octylamine, nonylamine, decylamine, dodecylamine, cetylamine, methylenediamine, ethylenediamine, and tetraethylenepentamine.

The hindered amine compounds are not particularly limited, but the following are preferable. Examples include, p,p′-dioctyldiphenylamine (product name: Irganox 5057), phenyl-α-naphthylamine (product name: Nocrac PA), poly(2,2,4-trimethyl-1,2-dihydroquinoline) (product name: Nocrac 224, 224-S), 6-ethoxy-2,2,4-trimethyl-1,2-dihydroquinoline (product name: Nocrac AW), N,N′-diphenyl-p-phenylenediamine (product name: Nocrac DP), N,N′-di-β-naphthyl-p-phenylenediamine (product name: Nocrac White), N-phenyl-N′-isopropyl-p-phenylenediamine (product name: Nocrac 810NA), N, N′-diallyl-p-phenylenediamine (product name: Nonflex TP), 4,4′-(α,α-dimethylbenzyl)diphenylamine (product name: Nocrac CD), p,p-toluenesulfonylaminodiphenylamine (product name: Nocrac TD), N-phenyl-N′-(3-methacryloyloxy-2-hydroxypropyl)-p-phenylenediamine (product name: Nocrac G1), N-(1-methylheptyl)-N′-phenyl-p-phenylenediamine (product name: Ozonon 35), N,N′-di-sec-butyl-p-phenylenediamine (product name: Sumilizer BPA), N-phenyl-N′-1,3-dimethylbutyl-p-phenylenediamine (product name: Antigene 6C), alkylated diphenylamine (product name: Sumilizer 9A), a dimethyl succinate-1-(2-hydroxyethyl)-4-hydroxy-2,2,6,6-tetramethylpiperidine polycondensate (product name: Tinuvin 622LD), poly[[6-(1,1,3,3-tetramethylbutyl)amino-1,3,5-triazine-2,4-diyl][(2,2, 6, 6-tetramethyl-4-piperidyl)imino]hexamethylene[(2,2,6,6-tetramethyl-4-piperidyl)imino]](product name: CHIMASSORB 944), an N,N′-bis(3-aminopropyl)ethylenediamine-2,4-bis[N-butyl-N-(1,2,2,6,6-pentamethyl-4-piperidyl)amino]-6-chloro-1,3,5-triazine condensate (product name: CHIMASSORB 119FL), bis(1-octyloxy-2,2,6,6-tetramethyl-4-piperidyl) sebacate (product name: TINUVIN 123), bis(2,2,6,6-tetramethyl-4-piperidyl) sebacate (product name: TINUVIN 770), bis(1,2,2,6,6-pentamethyl-4-piperidyl) 2-(3,5-di-tert-butyl-4-hydroxybenzyl)-2-n-butylmalonate (product name: TINUVIN 144), bis(1,2,2,6,6-pentamethyl-4-piperidyl) sebacate (product name: TINUVIN 765), tetrakis(1,2,2,6,6-pentamethyl-4-piperidyl)1,2,3,4-butanetetracarboxylate (product name: LA-57), tetrakis(2,2,6,6-tetramethyl-4-piperidyl)1,2,3,4-butanetetracarboxylate (product name: LA-52), a mixed esterified product of 1,2,3,4-butanetetracarboxylic acid, 1,2,2,6,6-pentamethyl-4-piperidinol, and 1-tridecanol (product name: LA-62), a mixed esterified product of 1,2,3,4-butanetetracarboxylic acid, 2,2,6,6-tetramethyl-4-piperidinol, and 1-tridecanol (product name: LA-67), a mixed esterified product of 1,2,3,4-butanetetracarboxylic acid, 1,2,2,6,6-pentamethyl-4-piperidinol, and 3,9-bis(2-hydroxy-1,1-dimethylethyl)-2,4,8,10-tetraoxaspiro[5.5]undecane (product name: LA-63P), a mixed esterified product of 1,2,3,4-butanetetracarboxylic acid, 2,2,6,6-tetramethyl-4-piperidinol, and 3,9-bis(2-hydroxy-1,1-dimethylethyl)-2,4,8,10-tetraoxaspiro[5.5]undecane (product name: LA-68LD), (2,2,6,6-tetramethylene-4-piperidyl)-2-propylenecarboxylate (product name: ADK STAB LA-82), and (1,2,2,6,6-pentamethyl-4-piperidyl)-2-propylenecarboxylate (product name: ADK STAB LA-87).

Content amount of the component (G) is not particularly limited, but the content amount is preferably 0.01 to 1 mass % in the inventive photosensitive resin composition, when component (G) is contained.

### [Other Additives]

The inventive photosensitive resin composition may contain other additives, besides the above-described components. Examples of the other additives include a surfactant commonly used to improve coatability.

The surfactant is preferably nonionic. For example, it is fluorine-based surfactants, and specific examples thereof include perfluoroalkyl polyoxyethylene ethanols, fluorinated alkyl esters, perfluoroalkylamine oxides, and fluorine-containing organosiloxane-based compounds. For these, commercially available products may be used. Examples thereof include Fluorad (registered trademark) “FC-430” (manufactured by 3M Company); Surflon (registered trademark) “S-141” and “S-145” (manufactured by AGC SEIMI CHEMICAL CO., LTD.); UNIDYNE (registered trademark) “DS-401”, “DS-4031”, and “DS-451” (manufactured by DAIKIN INDUSTRIES, LTD.); Megafac (registered trademark) “F-8151” (manufactured by DIC Corporation); and “X-70-093” (manufactured by Shin-Etsu Chemical Co., Ltd.). Among these, Fluorad FC-430 and X-70-093 are preferable. The content amount of the surfactant is preferably 0.01 to 5 parts by mass relative to 100 parts by mass of the component (A).

The inventive photosensitive resin composition may contain a silane coupling agent as other additives. Incorporating a silane coupling agent can further enhance the adhesiveness of a resin film obtained from the photosensitive resin composition to the body to be adhered. Examples of the silane coupling agents include epoxy group-containing silane coupling agents and aromatic group-containing amino silane coupling agents. One kind of these may be used alone or two or more kinds thereof may be used in combination. The content of the silane coupling agent is not particularly limited, but the content ratio is preferably 0.01 to 5 mass % of the inventive photosensitive resin composition when the silane coupling agent is contained.

The inventive photosensitive resin composition can be prepared according to a conventional method. For example, by mixing the components by stirring, and then filtering with a filter or the like as necessary, the inventive photosensitive resin composition can be prepared.

The inventive photosensitive resin composition has excellent dispersion stability in varnish, suppresses aggregates in a film, and can be used as a material for optical members (optical member application) that require shielding.

### [Pattern Forming Process Using Photosensitive Resin Composition]

The inventive pattern forming process using the inventive photosensitive resin composition includes steps of:
(i) forming a photosensitive resin film on a substrate by using the inventive photosensitive resin composition;
(ii) exposing the photosensitive resin film; and
(iii) developing the exposed photosensitive resin film with a developer to form a pattern.

The step (i) is a step in which a photosensitive resin film is formed on a substrate by using the inventive photosensitive resin composition. Examples of the substrate include a silicon wafer, a silicon wafer for through-electrodes, a silicon wafer made into a thin film by rear surface polishing, a plastic or ceramic substrate, a substrate that has metals such as Ni and Au on the entire surface or a part of the substrate by ion sputtering method, and plating method. In some cases, it is also possible to use a substrate having either or both of a groove and a hole, which has an opening width of 10 to 100 μm and a depth of 10 to 120 μm. Incidentally, an opening width and a depth of the groove or the hole of a substrate can be measured by a scanning electron microscope.

Methods to form the inventive photosensitive resin film include, for example, applying the inventive photosensitive resin composition onto the substrate by a method such as a dip method, a spin coating method, a roll coating method, and then pre-heating (pre-baking: PB) to proceed a photocuring reaction efficiently as necessary. The pre-heating can be performed at 40 to 140° C. for about 1 minute to 1 hour for example.

The amount of the above photosensitive resin composition applied can be appropriately selected depending on the purpose, but it is preferable to apply the composition so that the film thickness is 0.1 to 200 μm, preferably 1 to 150 μm.

To enhance the film thickness uniformity on a substrate surface, a solvent may be dropped on the substrate before the photosensitive resin composition is applied (pre-wetting method). The solvent to be dropped and its amount can be appropriately selected in accordance with the purpose. Preferable examples of the solvent include: alcohols such as isopropyl alcohol (IPA); ketones such as cyclohexanone; and glycols such as PGME. It is also possible to use the solvent used for the inventive photosensitive resin composition.

Then, (ii) exposing the photosensitive resin film is performed. The exposure is preferably performed with light having a wavelength of 1 to 600 nm, more preferably 10 to 600 nm, and further preferably 190 to 500 nm. The light having such wavelengths are, for example, various light generated from a radiation generator and having a different wavelength. Examples thereof include: ultraviolet light such as a g-line, an h-line, and an i-line; and far ultraviolet light (248 nm, 193 nm). Among these, light having a wavelength of 248 to 436 nm is particularly preferable. The exposure dose is preferably 10 to 10000 mJ/cm².

The exposure may be performed via a photomask. The photomask may, for example, be hollowed out in a desired pattern. Incidentally, the material of the photomask is not particularly limited, but is preferably one that blocks light having the aforementioned wavelength. For example, a photomask having a light-blocking film made of chromium is suitably used.

Further, in order to enhance the development sensitivity, the post-exposure baking (PEB) may be carried out. The PEB is preferably performed at 40 to 150° C. for 0.5 to 10 minutes. PEB makes the exposed part crosslinked to form an insoluble pattern that is insoluble in an organic solvent used as a developer.

After the exposure or PEB, (iii) developing with a developer to form a pattern is performed. The developer is preferably alcohols such as IPA, ketones such as cyclohexanones, glycols such as PGME, etc. It is also possible to use the solvent used for the inventive photosensitive resin composition. Examples of the development method may be a conventional method, and its examples include a method in which the patterned substrate is soaked into the developer. Then, if necessary, washing, rinsing, drying, etc. are carried out to obtain a photosensitive resin film having a desired pattern.

Further, as in the step (iv), the patterned photosensitive resin film is preferably post-cured by using an oven or hot plate at 100° C. to 250° C., more preferably 150 to 220° C. When the post-curing is performed at 100° C. to 250° C., it is possible to increase the crosslinking density of the photosensitive resin composition and remove residual volatile components, and thus it is more preferable from the viewpoints of adhesiveness to a substrate, heat resistance, strength, electrical properties, and adhesive strength. The post-curing time is preferably 10 minutes to 10 hours, more preferably 10 minutes to 3 hours. By using the inventive photosensitive resin composition, a film having excellent various film properties can be obtained even when post-curing is performed at a relatively low temperature around 200° C. Thickness of the film (cured film) after the post-curing is normally 1 to 200 μm, preferably 5 to 50 μm.

When it is unnecessary to form a pattern, for example, when it is simply desired to form a uniform photosensitive resin film, in the step (ii) of the pattern forming process the resin film may be exposed to radiation having a suitable wavelength without using a photomask to form a film.

### [Photosensitive Dry Film]

The inventive photosensitive dry film includes a support film and a photosensitive resin film obtained from the inventive photosensitive resin composition on the support film.

The above photosensitive dry film, which includes a support film and a photosensitive resin film, is solid, and the photosensitive resin film does not contain a solvent. Accordingly, there is no risk that bubbles due to the volatilization of the solvent remain in the photosensitive resin film and between the film and a substrate having asperities. In consideration of flatness on the substrate having asperities on its surface, step-covering properties, and a lamination interval of substrates, there exists an appropriate range of the film thickness. The thickness of the photosensitive resin film is preferably 5 to 200 μm, more preferably 10 to 100 μm.

In addition, the viscosity and fluidity of the photosensitive resin film are closely related. The photosensitive resin film in an appropriate viscosity range can exhibit appropriate fluidity; can deeply enters a narrow gap; and can enhance adhesiveness to a substrate by softening of the resin. Accordingly, the photosensitive resin film has preferably a viscosity of 10 to 5000 Pa·s, more preferably 30 to 2,000 Pa·s, further preferably 50 to 300 Pa·s, at 80 to 120° C., from the viewpoint of the fluidity of the photosensitive resin film. Incidentally, in the present invention, the viscosity is a value measured with a rotational viscometer.

When the inventive photosensitive dry film is brought into close contact with a substrate (e.g., a substrate having either or both of a groove and a hole, which has an opening width of 10 to 100 μm and a depth of 10 to 120 μm.) having asperities on its surface, the photosensitive resin film fits in and covers the asperities, so that high flatness can be achieved. Particularly, the inventive photosensitive resin composition has flexibility, so that higher planarization can be achieved. Further, when the photosensitive resin film was brought into close contact with the substrate under vacuum environment, it is possible to prevent a gap between them more effectively.

The inventive photosensitive dry film can be produced by applying the inventive photosensitive resin composition onto a substrate (support film) and drying the composition to form a photosensitive resin film. As manufacturing apparatus for the photosensitive dry film, it is possible to employ a film coater which is commonly used to produce adhesive products. Examples of the film coater include a comma coater, a comma reverse coater, a multi coater, a die coater, a lip coater, a lip reverse coater, a direct gravure coater, an offset gravure coater, a 3-roll bottom reverse coater, and a 4-roll bottom reverse coater.

The photosensitive dry film can be produced by: applying the inventive photosensitive resin composition onto the support film to have a predetermined thickness when the support film is rolled-out from a roll-out shaft of the film coater and passes through a coater head of the film coater; and then having the resultant passed through a hot-air circulating oven at a predetermined temperature for a predetermined period and dried on the support film to form the photosensitive resin film. The photosensitive dry film with a protective film can be produced by: passing the photosensitive dry film through a laminate roll under a predetermined pressure together with the protective film that was rolled-out from another roll-out shaft of the film coater to stick the protective film and the photosensitive resin film together on the support film; and subsequently winding up the resulting laminate to a winding shaft of the film coater. In this event, the temperature is preferably 25 to 150° C., the period is preferably 1 to 100 minutes, and the pressure is preferably of 0.01 to 5 MPa.

The support film may be a monolayer film composed of a single film or a multilayer film composed of multiple laminated polymer films. Examples of the material of the film include synthetic resin films such as polyethylene, polypropylene, polycarbonate, and polyethylene terephthalate. Among these, polyethylene terephthalate is a preferable material because of having appropriate flexibility, mechanical strength, and heat resistance. These films may have been subjected to various treatments such as corona treatment and coating treatment with a releasing agent. Commercial products may be used for these. Examples thereof include: Cerapeel WZ (RX) and Cerapeel BX8 (R), both are manufactured by Toray Advanced Film Co., Ltd.; E7302 and E7304, both are manufactured by Toyobo Co., Ltd.; Purex G31 and Purex G71T1, both are manufactured by Teijin DuPont Films Japan Ltd.; and PET38×1-A3, PET38×1-V8, and PET38×1-X08, all manufactured by Nippa Co., Ltd.

The protective film to be used may be the same film as the above support film, but polyethylene terephthalate and polyethylene are preferable because they have appropriate flexibility. Commercial products may be used for these. Examples thereof include: the polyethylene terephthalates exemplified above; and polyethylenes such as GF-8 manufactured by Tamapoly Co., Ltd. and PE Film 0-Type manufactured by Nippa Co. Ltd.

The thicknesses of both the support film and the protective film are preferably 10 to 100 μm, more preferably 25 to 50 μm, from the viewpoints of stable production of the photosensitive dry film, prevention of rolling habit around a roll shaft, and so-called “curl-prevention.”

### [Pattern Forming Process Using Photosensitive Dry Film]

The pattern forming process by using the inventive photosensitive dry film includes steps of:
(i) forming a photosensitive resin film on a substrate by using the inventive photosensitive dry film;
(ii) exposing the photosensitive resin film; and
(iii) developing the exposed photosensitive resin film with a developer to form a pattern.

First, in the step (i), the photosensitive dry film is used to form the photosensitive resin film on a substrate. Specifically, the photosensitive resin film of the photosensitive dry film is bonded to a substrate, to form the photosensitive resin film on the substrate. In the case where a protective film is laminated on the photosensitive dry film, after removing the protective film from the photosensitive dry film, the photosensitive resin film of the photosensitive dry film is bonded to the substrate. The bonding can be performed, for example, by using a film sticking apparatus.

Examples of the substrate include the same substrates as described in the above pattern forming process using the photosensitive resin composition. The film sticking apparatus is preferably a vacuum laminator. For example, the protective film of the photosensitive dry film is delaminated, and the uncovered photosensitive resin film is brought into close contact with the substrate on a table at a predetermined temperature by using a sticking roll under a predetermined pressure in a vacuum chamber with a predetermined degree of vacuum. Incidentally, the temperature is preferably 60 to 120° C., the pressure is preferably 0 to 5.0 MPa, and the degree of vacuum is preferably 50 to 500 Pa.

The attachment of the film may be repeated plural times if necessary to obtain a photosensitive resin film having the desired thickness. With repeating the attachment step 1 to 10 times or so, for example, it is possible to obtain a photosensitive resin film having a thickness of 10 to 1,000 μm, particularly about 100 to 500 μm.

In order to perform an efficient photocuring reaction of the photosensitive resin film and to improve adhesiveness between the photosensitive resin film and the substrate, pre-baking may be performed as necessary. The pre-baking can be performed, for example, at 40 to 140° C. for about 1 minute to 1 hour.

In the same manner as the pattern forming process using the photosensitive resin composition, the photosensitive resin film bonded on the substrate can have a pattern formed by (ii) exposing the photosensitive resin film, (iii) developing the exposed photosensitive resin film with a developer, and as necessary (iv) post-curing. Incidentally, the support film of the photosensitive dry film is delaminated before the pre-bake or before the PEB depending on the process or removed by other methods.

### EXAMPLE

Hereinafter, the present invention will be more specifically described with reference to Synthesis Examples, Comparative Synthesis Examples, Examples, and Comparative Examples. However, the present invention is not limited to the following Examples.

In the following Synthesis Example, the molecular weight (Mw) of each silicone resin is measured by GPC using TSKgel Super HZM-H manufactured by Tosoh Corporation as a column, tetrahydrofuran (THF) as an elution solvent, and monodisperse polystyrene as the standard, under analysis conditions with a flow rate of 0.6 mL/min and a column temperature of 40° C.

In Synthesis Examples 1-1 to 1-4 below, the silicone resins (polymers) used for preparation of the photosensitive resin compositions, Examples 1 to 9, were synthesized. Compounds (S-1) to (S-6) used in the synthesis of silicone resins are as follows.

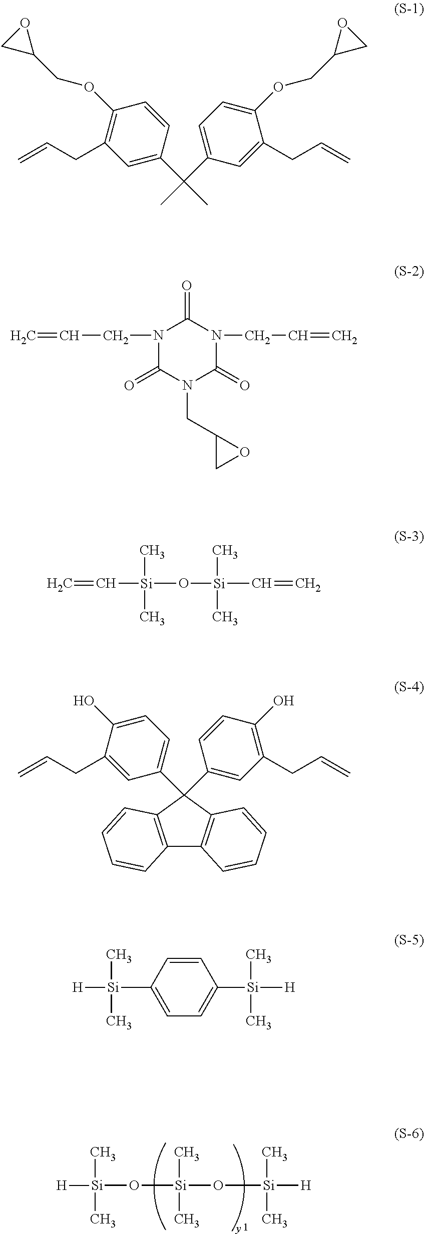

### [1] Synthesis of Polymers Having a Silicone Skeleton

### [Synthesis Example 1-1] Synthesis of Silicone Resin (1)

17.6 g (0.28 mol) of Compound (S-1), 79.5 g (0.3 mol) of Compound (S-2), and 79.9 g (0.43 mol) of Compound (S-3) were added to a 3 L flask equipped with a stirrer, a thermometer, a nitrogen purging device, and a reflux condenser, then 2,000 g of toluene was added and the mixture was heated to 70° C. Then 1.0 g of toluene solution of platinic chloride (platinum concentration 0.5 mass %) was added, and 67.9 g (0.35 mol) of Compound (S-5) and 399.8 g (0.65 mol) of Compound (S-6) (y¹=8) were added dropwise over 1 hour (total hydrosilyl group/total alkenyl group=1/1 (mole ratio)). After completion of the drop, the mixture was heated to 100° C. and aged for 6 hours, and then toluene was distilled off under reduced pressure from the reaction solution to obtain Silicone Resin (1). Silicone Resin (1) was confirmed to contain the repeating units a1, b1, a3, b3, a4, and b4 by ¹H-NMR (manufactured by Bruker Corporation). The molecular weight (Mw) of Silicone Resin (1) was 35,000 and the silicone content ratio was 64.4 mass %.

### [Synthesis Example 1-2] Synthesis of Silicone Resin (2)

109.2 g (0.26 mol) of Compound (S-1), 64.5 g (0.15 mol) of Compound (S-4), and 18.6 g (0.10 mol) of Compound (S-3) were added to a 3 L flask equipped with a stirrer, a thermometer, a nitrogen purging device, and a reflux condenser, then 2,000 g of toluene was added and the mixture was heated to 70° C. Then 1.0 g of toluene solution of platinic chloride (platinum concentration 0.5 mass %) was added, and 54.2 g (0.30 mol) of Compound (S-5) and 589.2 g (0.4 mol) of Compound (S-6) (y¹=38) were added dropwise over 1 hour (total hydrosilyl group/total alkenyl group=1/1 (mole ratio)). After completion of the drop, the mixture was heated to 100° C. and aged for 6 hours, and then toluene was distilled off under reduced pressure from the reaction solution to obtain Silicone Resin (2). Silicone Resin (2) was confirmed to contain the repeating units a1, b1, a2, b2, a4, and b4 by ¹H-NMR (manufactured by Bruker Corporation). The molecular weight (Mw) of Silicone Resin (2) was 42,000 and the silicone content ratio was 72.6 mass %.

### [Synthesis Example 1-3] Synthesis of Silicone Resin (3)

185.5 g (0.70 mol) of Compound (S-2) and 90.3 g (0.21 mol) of Compound (S-4) were added to a 3 L flask equipped with a stirrer, a thermometer, a nitrogen purging device, and a reflux condenser, then 2,000 g of toluene was added and the mixture was heated to 70° C. Then 1.0 g of toluene solution of platinic chloride (platinum concentration 0.5 mass %) was added, and 155.2 g (0.80 mol) of Compound (S-5) and 589.2 g (0.2 mol) of Compound (S-6) (y¹=38) were added dropwise over 1 hour (total hydrosilyl group/total alkenyl group=1/1 (mole ratio)). After completion of the drop, the mixture was heated to 100° C. and aged for 6 hours, and then toluene was distilled off under reduced pressure from the reaction solution to obtain Silicone Resin (3). Silicone Resin (3) was confirmed to contain the repeating units a2, b2, a3, b3, a4, and b4 by ¹H-NMR (manufactured by Bruker Corporation). The molecular weight (Mw) of Silicone Resin (3) was 32,000 and the silicone content ratio was 75.5 mass %.

### [Synthesis Example 1-4] Synthesis of Silicone Resin (4)

126.0 g (0.30 mol) of Compound (S-1), 55.7 g (0.21 mol) of Compound (S-2), and 215.0 g (0.50 mol) of Compound (S-4) were added to a 3 L flask equipped with a stirrer, a thermometer, a nitrogen purging device, and a reflux condenser, then 2,000 g of toluene was added and the mixture was heated to 70° C. Then 1.0 g of toluene solution of platinic chloride (platinum concentration 0.5 mass %) was added, and 67.9 g (0.35 mol) of Compound (S-5) and 399.8 g (0.65 mol) of Compound (S-6) (y¹=8) were added dropwise over 1 hour (total hydrosilyl group/total alkenyl group=1/1 (mole ratio)). After completion of the drop, the mixture was heated to 100° C. and aged for 6 hours, and then toluene was distilled off under reduced pressure from the reaction solution to obtain Silicone Resin (4). Silicone Resin (4) was confirmed to contain the repeating units a1, b1, a2, b2, a3, and b3 by ¹H-NMR (manufactured by Bruker Corporation). The molecular weight (Mw) of Silicone Resin (4) was 36,000 and the silicone content ratio was 58.4 mass %.

### [2] Synthesis of Acrylic Resins

In the following Synthesis Example 2-1 to 2-3, acrylic resins (polymers) used to prepare photosensitive resin compositions for the Comparative Examples 1 o 7 were synthesized

### [Synthesis Example 2-1] Synthesis of Acrylic Resin (1)

1 g of 2,2′-azobisisobutyronitrile (AIBN), 70 g of PGMEA (propylene glycol monomethyl ether acetate), and 70 g of toluene were charged to a flask equipped with a stirrer, a reflux condenser, an inert gas supply opening, and a thermometer. Next, the mixture was added with 55 g of acrylic acid and 56 g of methacrylic acid, stirred thoroughly under a nitrogen atmosphere, and heated to 80° C. The mixture was stirred for 6 hours while keeping the reaction temperature at 80° C.±2° C. to obtain a solution of Acrylic Resin (1). PGMEA was added to the obtained solution so that the concentration of Acrylic Resin (1) was 60 mass %. The molecular weight (Mw) of Acrylic Resin (1) was 28,000.

### [Synthesis Example 2-2] Synthesis of Acrylic Resin (2)

1 g of 2,2′-azobisisobutyronitrile (AIBN), 70 g of PGMEA (propylene glycol monomethyl ether acetate), and 70 g of toluene were charged to a flask equipped with a stirrer, a reflux condenser, an inert gas supply opening, and a thermometer. Next, the mixture was added with 50 g of acrylic acid and 79 g of methyl acrylate, stirred thoroughly under a nitrogen atmosphere, and heated to 80° C. The mixture was stirred for 6 hours while keeping the reaction temperature at 80° C.±2° C. to obtain a solution of Acrylic Resin (2). PGMEA was added to the obtained solution so that the concentration of Acrylic Resin (2) was 60 mass %. The molecular weight (Mw) of Acrylic Resin (2) was 32,000.

### [3] Preparation of Photosensitive Resin Compositions

### Examples 1 to 9 and Comparative Examples 1 to 7

Components each are blended according to the blending amounts shown in Table 1, and then the mixture was stirred, mixed, and dissolved at a normal temperature. Thereafter, the mixture was subjected to precision filtration with 1.0 μm filter made of Teflon (registered trademark) to obtain photosensitive resin compositions for Examples 1 to 9 and Comparative Examples 1 to 7.

TABLE 1

| | | Example | | | | | | | | |
|---|---|---|---|---|---|---|---|---|---|---|
| | | 1 | 2 | 3 | 4 | 5 | 6 | 7 | 8 | 9 |
| Polymer | Silicone resin (1) | 100 | 100 | | | | | | | |
| | Silicone resin (2) | | | 100 | | | | | | |
| | Silicone resin (3) | | | | 100 | | 100 | 100 | | |
| | Silicone resin (4) | | | | | 100 | | | 100 | 100 |
| Anthraquinone- | B-1 | 0.0 | 0.5 | 1.0 | 3.5 | 3.5 | 5.0 | 3.0 | | |
| based dye | B-2 | | | | | | | | 3.5 | |
| | B-3 | | | | | | | | | 3.5 |
| Photoacid | PAG-1 | 1 | 1 | 1 | 1 | 1 | 1 | 1 | 1 | 1 |
| generator | | | | | | | | | | |
| Crosslinking | CL-1 | | | 20 | 20 | 20 | 20 | 20 | 20 | 20 |
| agent | | | | | | | | | | |
| Antioxidant | F-1 | | | 0.1 | | 0.1 | | 0.1 | 0.1 | 0.1 |
| | F-2 | | | 0.1 | | 0.1 | | 0.1 | 0.1 | 0.1 |
| Solvent | Cyclopentanone | 55 | 55 | 55 | 55 | 55 | 55 | 55 | 55 | 55 |
| Quencher | AM-1 | | 0.1 | | 0.3 | 0.3 | 0.3 | 0.3 | | 0.3 |

TABLE 2

| | | Comparative Example | | | | | | |
|---|---|---|---|---|---|---|---|---|
| | | 1 | 2 | 3 | 4 | 5 | 6 | 7 |
| Polymer | Silicone resin (1) | 100 | 100 | | | | | |
| | Acrylic resin (1) | | | 50 | 50 | 50 | 50 | 50 |
| | Acrylic resin (2) | | | 50 | 50 | 50 | 50 | 50 |
| Anthraquinone- | B-1 | | | 0.5 | | 5.0 | | |
| based dye | B-2 | | | | 8.0 | | 3.5 | |
| | B-3 | | | | | | | 1.0 |
| Carbon black | HS-100 | 1 | 1.5 | | | | | |
| Photoacid generator | PAG-1 | 1 | 1 | | | | | |
| Photopolymerization | Irgasure | | | 1 | 1 | 1 | 1 | 1 |
| initiator | OXE-01 | | | | | | | |
| Crosslinking | CL-1 | 20 | 20 | | | | | |
| agent | CL-2 | | | 20 | 20 | 20 | 20 | 20 |
| Antioxidant | F-1 | 0.1 | 0.1 | 0.1 | 0.1 | 0.1 | 0.1 | 0.1 |
| | F-2 | 0.1 | 0.1 | 0.1 | 0.1 | 0.1 | 0.1 | 0.1 |
| Solvent | Cyclopentanone | 55 | 55 | | | | | |
| | PGMEA | | | 55 | 55 | 55 | 55 | 55 |

The antraquinone-based dyes B-1, B-2, and B-3, the photoacid generator PAG-1, photopolymerization initiator, the crosslinking agents CL-1 and CL-2, the antioxidants F-1 and F-2, and the quencher AM-1, which are shown in the Tables 1 and 2, are as follows.
B-1: SDO-14 (manufactured by Arimoto Chemical Co. Ltd), absorption maximum wavelength 758.5 nm (according to JIS K 0115:2020), melting point 250° C.
B-2: Macrolex Green G (manufactured by Bayer AG), absorption maximum wavelength 690 nm

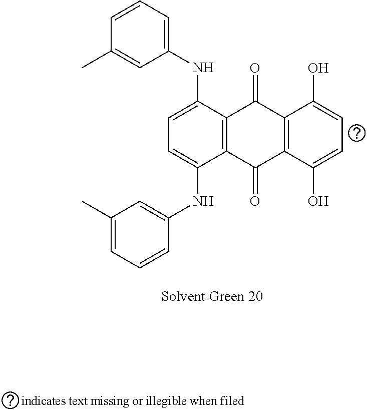 [SMILES: Cc1cccc(Nc2ccc(Nc3cccc(C)c3)c3c2C(=O)c2c(O)ccc(O)c2C3=O)c1]

B-3: Sumiplast GreenG (manufactured by Sumika Chemtex Company, Limited), absorption maximum wavelength 645 nm

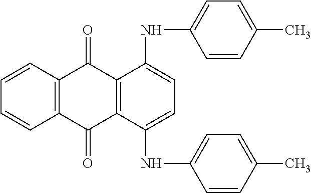 [SMILES: Cc1ccc(Nc2ccc(Nc3ccc(C)cc3)c3c2C(=O)c2ccccc2C3=O)cc1]

PAG-1

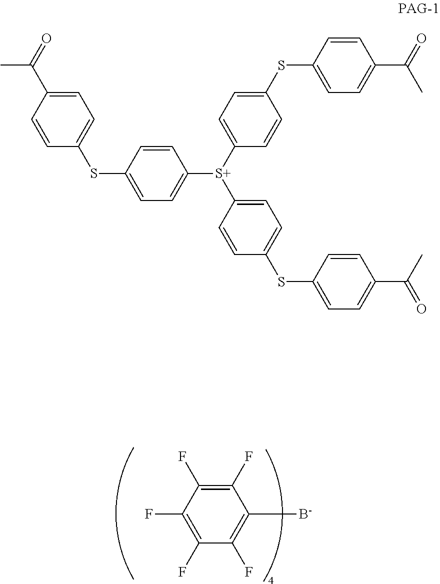

Photopolymerization initiator: Irgacure OXE01: manufactured by BASF Japan Ltd.

### CL-1, CL-2

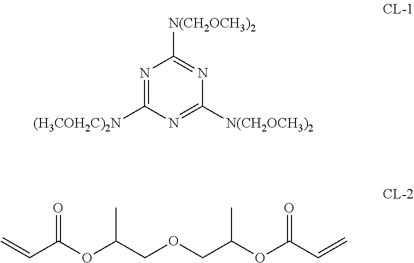

F-1: CHIMASSORB 119FL (made by BASF)
F-2: IRGANOX 3114 (made by BASF)
AM-1

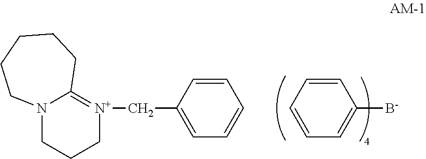

Carbon black: Acetylene black (HS-100, manufactured by Denka Company Limited, average primary particle size 45 nm)

### [4] Preparation of Photosensitive Dry Film

Using a die coater as a film coater and a polyethylene terephthalate film (thickness: 38 μm) as a support film, each photosensitive resin compositions of Examples 1 to 9 and Comparative examples 1 to 7 were respectively applied onto the support film. Then, the applied support film was dried by passing through a hot air circulating oven (length: 4 m) set at 100° C. for 5 minutes. Thereby, a photosensitive resin film was formed on the support film to obtain a photosensitive dry film. A polyethylene film (thickness: 40 μm) as a protective film was laminated onto the photosensitive resin film at a pressure of 1 MPa using a laminate roll, and a photosensitive dry film with a protective film was prepared. Thickness of photosensitive resin films each are shown in Tables 3 and 4. Incidentally, the thickness of a film was measured (in μm) by an optical interface film thickness measurement instrument (manufactured by SCREEN Semiconductor Solutions Co., Ltd.).

### [5] Evaluation of Photosensitive Resin Film

### (1) Evaluation of Pattern Formability

The protective film was stripped off from the photosensitive dry film with a protective film. By setting degree of vacuum of a vacuum chamber set at a vacuum of 80 Pa using a vacuum laminator TEAM-100RF (manufactured by Takatori Corp.), the photosensitive resin film on a support film was closely bonded to a silicone substrate having asperities. The temperature was 100° C. After returning to normal pressure, the substrate was taken out of the vacuum laminator, and the support film was stripped off. Next, the resin film was prebaked on a hot plate at 110° C. for 5 minutes for enhancing its adhesiveness to the substrate. And then, for forming a line-and-space pattern and a contact hole pattern in the obtained photosensitive resin film, the resin film was exposed to radiation of wavelength 365 nm via a mask using a contact aligner exposure apparatus. After exposure, the photosensitive resin film was baked (PEB) on a hot plate at 130° C. for 5 minutes and cooled, followed by spray development in PGMEA (propylene glycol monomethyl ether acetate) for 300 seconds to form a pattern.

The photosensitive resin film patterned by the above method on the substrate was post-cured in an oven at 180° C. for 2 hours while purging with nitrogen. Then, using a scanning electron microscope (SEM), the formed contact hole patterns of 50 μm, 40 μm, 30 μm, 20 μm, 10 μm, and 5 μm were observed in cross-section. The minimum diameter of patterned hole in which a hole extended down to the film bottom was defined as a maximum resolution. From the observed cross-sectional photo, the contact hole pattern of 40 μm was evaluated for perpendicularity, and rated “Excellent” for perpendicular pattern, “Good” for slight inversely tapered profile, “Fair” for inversely tapered profile, and “Poor” for opening failure. The results are shown in Tables 3 and 4.

### (2) Evaluation of Compatibility

Each of the photosensitive resin compositions of Examples 1 to 9 and Comparative Examples 1 to 7 was visually checked for the presence or absence of precipitate when the photosensitive resin compositions were allowed to stand at 23° C. for 24 hours. A sample with no precipitate after 24 hours was graded as “Excellent,” a sample with no problem for 12 hours but with precipitate within 24 hours was graded as “Fair,” and a sample with precipitate within 12 hours was graded “Poor.” The results are shown in Tables 3 and 4.

### (3) Evaluation of Reliability (Adhesiveness, Crack Resistance)

A silicon wafer was coated with one of photosensitive resin composition of Examples 1 to 9 and Comparative Examples 1 to 7 using a spin coater so that the composition has a thickness of 10 μm. In order to remove the solvent, the composition was dried by heating at 100° C. for 3 minutes on a hot plate.

The entire surface of the photosensitive resin composition coated on the wafer was irradiated with light (wavelength 365 nm) radiated from a high-pressure mercury lamp as a light source using SUSS MicroTec's Mask Aligner MA8 without using a mask, baked (PEB) at 140° C. for 5 minutes, and soaked in PGMEA for 5 minutes. The film remaining after this operation was heated in an oven at 190° C. for 1 hour to obtain a photosensitive resin film.

The obtained wafer was cut to give a test piece in a size of 10 mm×10 mm square by using a dicing saw (DAD685 manufactured by DISCO CORPORATION, spindle rotation speed: 40,000 rpm, cutting rate: 20 mm/sec) equipped with a dicing blade. The obtained test pieces (10 pieces for each) were subjected to a heat cycle test (repeated 1000 cycles of holding at −25° C. for 10 minutes and holding at 125° C. for 10 minutes) and the state of peeling off of the resin film from the wafer and existence of a crack after the heat cycle test were observed by an optical microscope. The example which showed no peeling and no crack was rated as “Good”, the example in which at least one test piece showed peeling was rated as “Peel”, and the example in which at least one test piece showed a crack was rated as “Crack”. The results are shown in Tables 3 and 4.

### (4) Evaluation of Heat Resistance

Mass of the test piece prepared in the evaluation of reliability was measured as “before testing”; the test piece was left in an oven heated at 200° C. for 1,000 hours; the test piece was taken out from the oven; and mass of the test piece was measured as “after testing”. The test piece in which the weight change was less than 0.5% by mass between “before testing” and “after testing” was judged as “Good,” and the test piece in which the weight change was 0.5% by mass or more between “before testing” and “after testing” was judged as “Bad.” The results are shown in Tables 3 and 4.

### (5) Evaluation of Light-Shielding Property

The entire surface of the photosensitive resin film that was formed by laminating a photosensitive dry film made on a glass wafer was irradiated with light (wavelength 360 nm) radiated from a high-pressure mercury lamp as a light source using SUSS MicroTec's Mask Aligner MA8 without using a mask, baked (PEB), and soaked in PGMEA. The film remaining after this operation was further heated in an oven at 190° C. for 2 hours to obtain a cured film. Regarding this film, the transmittance (unit: %) of visible light having a wavelength of 800 nm or less was measured using a spectrophotometer U-3900H (manufactured by Hitachi High-Tech Science Co., Ltd.). The maximum transmittance in the measurements is shown in Tables 3 and 4.

### (6) Aggregates in a Film

1 m peace of the prepared dry film was cut out from an arbitrary location, and the presence of aggregates was observed using an optical microscope. Those in which the maximum diameter of aggregates was less than 1 μm were judged as “Good,” and those in which the maximum diameter of aggregates was 1 μm or more were judged as “Poor.”

The evaluation results of the resin films obtained by using the photosensitive resin compositions and the dry film each described in Tables 1 and 2 are shown in Tables 3 and 4, respectively.

TABLE 3

| | | Example | | | | | | |
|---|---|---|---|---|---|---|---|---|
| | | 1 | 2 | 3 | 4 | 5 | 6 | 7 |
| Thickness of | | 10 | 10 | 10 | 10 | 10 | 10 | 10 |
| resin layer (μm) | | | | | | | | |
| Profile of | | Excellent | Good | Good | Excellent | Good | Good | Excellent |
| contact hole pattern | | | | | | | | |
| Maximum resolution (μm) | | 10 | 5 | 10 | 10 | 10 | 10 | 10 |
| Compatibility | | Good | Good | Good | Good | Good | Good | Good |
| Reliability | Adhesiveness | Good | Good | Good | Good | Good | Good | Good |
| | Crack Resistance | Good | Good | Good | Good | Good | Good | Good |

| | | | | | | | |
|---|---|---|---|---|---|---|---|
| Heat resistance | Good | Good | Good | Good | Good | Good | Good |
| Thickness of film (μm) | 15 | 15 | 15 | 10 | 15 | 10 | 15 |
| Transmittance @ | 5 | 5 | 10 | 10 | 10 | 5 | 5 |
| 800 nm or less (%) | | | | | | | |
| Aggregate in film | Good | Good | Good | Good | Good | Good | Good |

TABLE 4

| | | Comparative Example | | | | | | |
|---|---|---|---|---|---|---|---|---|
| | | 1 | 2 | 3 | 4 | 5 | 6 | 7 |
| Thickness of | | 10 | 10 | 10 | 10 | 10 | 10 | 10 |
| resin layer (μm) | | | | | | | | |
| Profile of | | Fair | Poor | Fair | Poor | Poor | Poor | Poor |
| contact hole pattern | | | | | | | | |
| Maximum resolution (μm) | | 10 | — | 50 | — | — | — | — |
| Compatibility | | Fair | Poor | Fair | Poor | Poor | Poor | Poor |
| Reliability | Adhesiveness | Peeled | Peeled | Peeled | Peeled | Peeled | Peeled | Peeled |
| | Crack Resistance | Cracked | Cracked | Cracked | Cracked | Cracked | Cracked | Cracked |

| | | | | | | | |
|---|---|---|---|---|---|---|---|
| Heat resistance | Bad | Bad | Bad | Bad | Bad | Bad | Bad |
| Thickness of film (μm) | 15 | 15 | 10 | 10 | 10 | 10 | 10 |
| Transmittance @ | 5 | 5 | 40 | 30 | 25 | 30 | 40 |
| 800 nm or less (%) | | | | | | | |
| Aggregate in film | Good | Poor | Poor | Poor | Poor | Poor | Poor |

As shown in Table 3, Examples 1 to 9 using the inventive photosensitive resin composition were found to have no film aggregates, were good in a profile of a contact hole pattern, maximum resolution, compatibility, reliability (adhesiveness, crack resistance), and heat resistance, and have light-shielding properties. On the other hand, as shown in Table 4, Comparative Examples 1 to 7 were found to be inferior to Examples in the profile of a contact hole pattern, maximum resolution, compatibility, reliability (adhesiveness, crack resistance), and heat resistance.

From the above results, the inventive photosensitive resin composition was found to be able to form a light-shielding cured product that has excellent dispersion stability in varnish, no aggregates in a film, good reliability (adhesiveness, crack resistance), good heat resistance, and good resolution.

The present description includes the following embodiments.

[1]: A photosensitive resin composition comprising a silicone skeleton-containing polymer (A), an anthraquinone-based dye (B), and a photoacid generator (C).
[2]: The photosensitive resin composition of the above [1], wherein
the silicone skeleton-containing polymer (A) comprises repeating units represented by the following formulae (a1) to (a4) and (b1) to (b4),

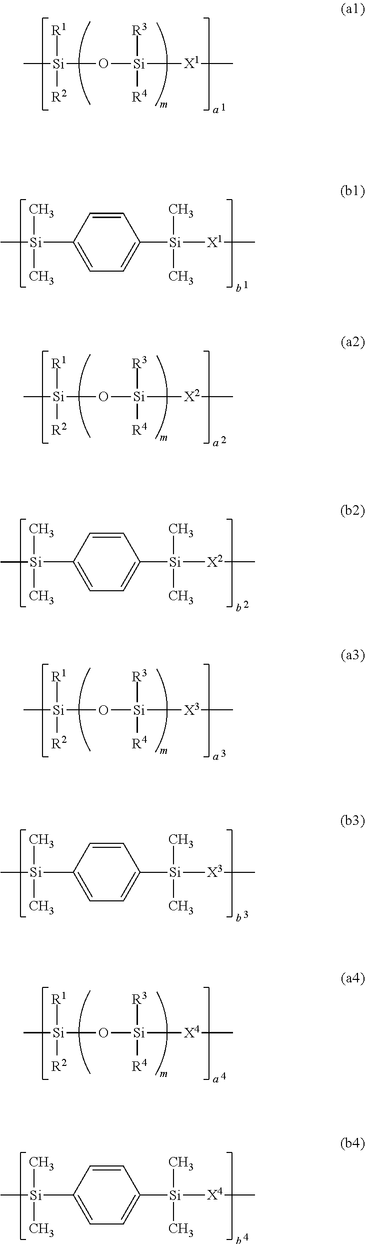

wherein R¹ to R⁴ each independently represent a monovalent hydrocarbon group having 1 to 8 carbon atoms; “m” represents an integer of 1 to 600; a¹ to a⁴ and b1 to b⁴ represent numbers satisfying 0≤a¹<1, 0≤a²<1, 0≤a³<1, 0≤a⁴<1, 0≤b¹<1, 0≤b²<1, 0≤b³<1, 0≤b⁴<1, 0≤a¹+a²+a³+a⁴<1, 0<b¹+b²+b³+b⁴<1, and a¹+a²+a³+a⁴+b1+b2+b3+b4=1; X¹ represents a divalent group represented by the following formula (X1); X² represents a divalent group represented by the following formula (X2); X³ represents a divalent group represented by the following formula (X3); and X⁴ represents a divalent group represented by the following formula (X4),

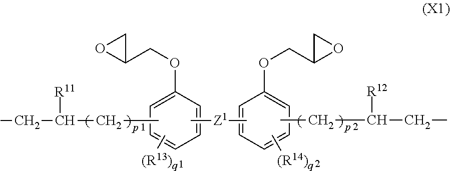

wherein Z¹ represents a single bond, a methylene group, a propane-2,2-diyl group, a 1,1,1,3,3,3-hexafluoropropane-2,2-diyl group, or a fluorene-9,9-diyl group; R¹¹ and R¹² each independently represent a hydrogen atom or a methyl group; R¹³ and R¹⁴ each independently represent an alkyl group having 1 to 4 carbon atoms or an alkoxy group having 1 to 4 carbon atoms; p¹ and p² each independently represent an integer of 0 to 7; and q¹ and q² each independently represent an integer of 0 to 2,

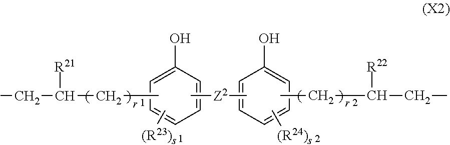

wherein Z² represents a single bond, a methylene group, a propane-2,2-diyl group, a 1,1,1,3,3,3-hexafluoropropane-2,2-diyl group, or a fluorene-9,9-diyl group; R²¹ and R²² each independently represent a hydrogen atom or a methyl group; R²³ and R²⁴ each independently represent an alkyl group having 1 to 4 carbon atoms or an alkoxy group having 1 to 4 carbon atoms; r¹ and r² each independently represent an integer of 0 to 7; and s¹ and s² each independently represent an integer of 0 to 2,

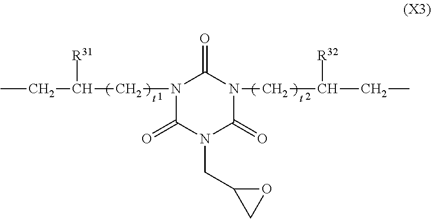

wherein R³¹ and R³² each independently represent a hydrogen atom or a methyl group; and t¹ and t² each independently represent an integer of 0 to 7,

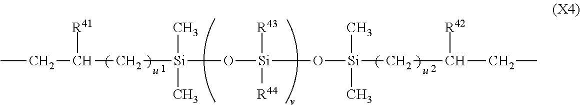

wherein R⁴¹ and R⁴² each independently represent a hydrogen atom or a methyl group; R⁴³ and R⁴⁴ each independently represent a monovalent hydrocarbon group having 1 to 8 carbon atoms; u¹ and u² each independently represent an integer of 0 to 7; and “v” represents an integer of 0 to 600.
[3]: The photosensitive resin composition of the above [1] or [2], further comprising any one or more of a crosslinking agent (D), a solvent (E), a quencher (F), and an antioxidant (G).
[4]: The photosensitive resin composition of the above [1], [2], or [3], wherein the anthraquinone-based dye (B) is contained in a 0.01 to 50 parts by mass relative to 100 parts by mass of the component (A).
[5]: The photosensitive resin composition of any one of the above [1] to [4], wherein the anthraquinone-based dye (B) has an absorption maximum wavelength of 800 nm or less.
[6]: The photosensitive resin composition of any one of the above [1] to [5], which is used for an optical member.
[7]: A photosensitive resin film obtained from the photosensitive resin composition of any one of the above [1] to [6].
[8]: A photosensitive dry film comprising a support film and the photosensitive resin film of the above [7] on the support film.
[9]: A pattern forming process by using a photosensitive resin composition, comprising:
(i) forming a photosensitive resin film on a substrate by using the photosensitive resin composition of any one of the above [1] to [6];
(ii) exposing the photosensitive resin film; and
(iii) developing the exposed photosensitive resin film with a developer to form a pattern.
   [10]: A pattern forming process by using a photosensitive dry film, comprising:
(i) forming a photosensitive resin film on a substrate by using the photosensitive dry film of the above [8];
(ii) exposing the photosensitive resin film; and
(iii) developing the exposed photosensitive resin film with a developer to form a pattern.
   [11]: The pattern forming process of the above [9] or [10], further comprising (iv) post-curing the photosensitive resin film at a temperature of 100° C. to 250° C., which has a pattern formed by development.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A photosensitive resin composition comprising a silicone skeleton-containing polymer (A), an anthraquinone-based dye (B), and a photoacid generator (C).

2. The photosensitive resin composition according to claim 1, wherein
the silicone skeleton-containing polymer (A) comprises repeating units represented by the following formulae (a1) to (a4) and (b1) to (b4), 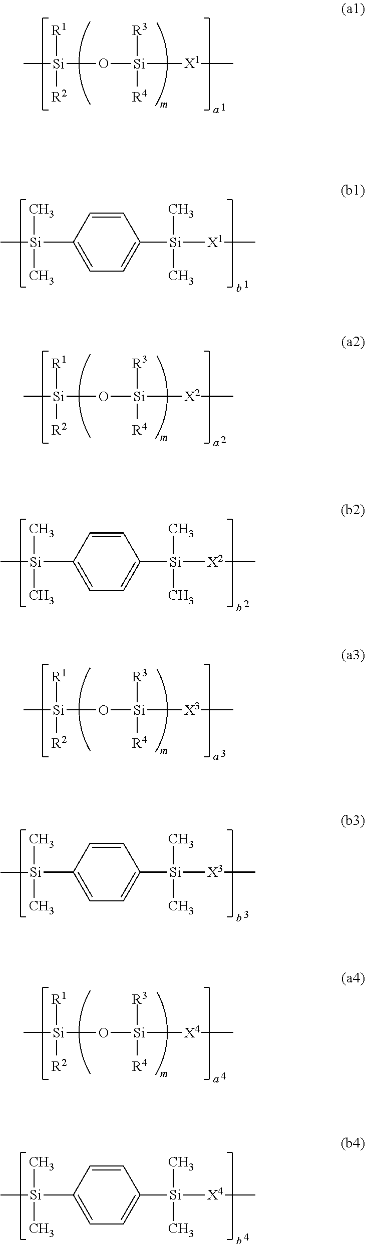
wherein R¹ to R⁴ each independently represent a monovalent hydrocarbon group having 1 to 8 carbon atoms; “m” represents an integer of 1 to 600; a¹ to a⁴ and b¹ to b⁴ represent numbers satisfying 0≤a¹<1, 0≤a²<1, 0≤a³<1, 0≤a⁴<1, 0≤b¹<1, 0≤b²<1, 0≤b³<1, 0≤b⁴<1, 0<a¹+a²+a³+a⁴<1, 0<b¹+b²+b³+b⁴<1, and a¹+a²+a³+a⁴+b¹+b²+b³+b⁴=1; X¹ represents a divalent group represented by the following formula (X1); X² represents a divalent group represented by the following formula (X2); X³ represents a divalent group represented by the following formula (X3); and X⁴ represents a divalent group represented by the following formula (X4), 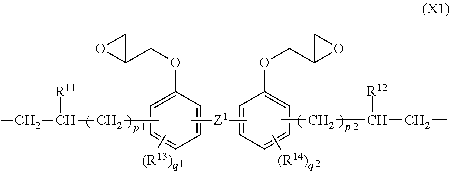
wherein Z¹ represents a single bond, a methylene group, a propane-2,2-diyl group, a 1,1,1,3,3,3-hexafluoropropane-2,2-diyl group, or a fluorene-9,9-diyl group; R¹¹ and R¹² each independently represent a hydrogen atom or a methyl group; R¹³ and R¹⁴ each independently represent an alkyl group having 1 to 4 carbon atoms or an alkoxy group having 1 to 4 carbon atoms; p¹ and p² each independently represent an integer of 0 to 7; and q¹ and q² each independently represent an integer of 0 to 2, 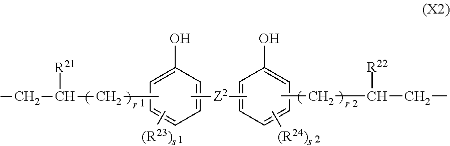
wherein Z² represents a single bond, a methylene group, a propane-2,2-diyl group, a 1,1,1,3,3,3-hexafluoropropane-2,2-diyl group, or a fluorene-9,9-diyl group; R²¹ and R²² each independently represent a hydrogen atom or a methyl group; R²³ and R²⁴ each independently represent an alkyl group having 1 to 4 carbon atoms or an alkoxy group having 1 to 4 carbon atoms; r¹ and r² each independently represent an integer of 0 to 7; and s¹ and s² each independently represent an integer of 0 to 2, 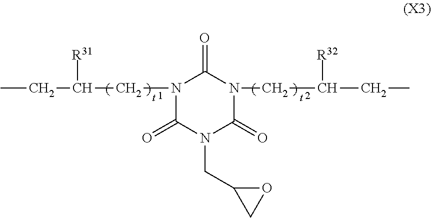
wherein R³¹ and R³² each independently represent a hydrogen atom or a methyl group; and t¹ and t² each independently represent an integer of 0 to 7, 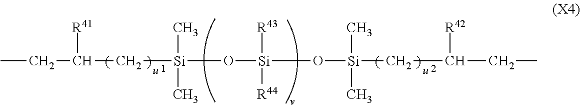
wherein R⁴¹ and R⁴² each independently represent a hydrogen atom or a methyl group; R⁴³ and R⁴⁴ each independently represent a monovalent hydrocarbon group having 1 to 8 carbon atoms; u¹ and u² each independently represent an integer of 0 to 7; and “v” represents an integer of 0 to 600.

3. The photosensitive resin composition according to claim 1, further comprising any one or more of a crosslinking agent (D), a solvent (E), a quencher (F), and an antioxidant (G).

4. The photosensitive resin composition according to claim 1, wherein the anthraquinone-based dye (B) is contained in a 0.01 to 50 parts by mass relative to 100 parts by mass of the component (A).

5. The photosensitive resin composition according to claim 1, wherein the anthraquinone-based dye (B) has an absorption maximum wavelength of 800 nm or less.

6. The photosensitive resin composition according to claim 1, which is used for an optical member.

7. A photosensitive resin film obtained from the photosensitive resin composition according to claim 1.

8. A photosensitive dry film comprising a support film and the photosensitive resin film according to claim 7 on the support film.

9. A pattern forming process by using a photosensitive resin composition, comprising:
(i) forming a photosensitive resin film on a substrate by using the photosensitive resin composition according to claim 1;
(ii) exposing the photosensitive resin film; and
(iii) developing the exposed photosensitive resin film with a developer to form a pattern.

10. A pattern forming process by using a photosensitive dry film, comprising:
(i) forming a photosensitive resin film on a substrate by using the photosensitive dry film according to claim 8;
(ii) exposing the photosensitive resin film; and
(iii) developing the exposed photosensitive resin film with a developer to form a pattern.

11. The pattern forming process according to claim 9 further comprising (iv) post-curing the photosensitive resin film at a temperature of 100° C. to 250° C., which has a pattern formed by development.

12. The pattern forming process according to claim 10 further comprising (iv) post-curing the photosensitive resin film at a temperature of 100° C. to 250° C., which has a pattern formed by development.
